(19) United States
(12) Patent Application Publication
(10) Pub. No.: US 2026/0331049 A1
(43) Pub. Date: Oct. 22, 2026

(54) DISPLAY DEVICE AND ELECTRONIC DEVICE INCLUDING THE SAME

(71) Applicant: Samsung Display Co., Ltd., Yongin-si (KR)

(72) Inventors: YONGHEE LEE, Yongin-si (KR); KYUNG-BAE KIM, Yongin-si (KR); DONGWOO KIM, Yongin-si (KR)

(21) Appl. No.: 19/468,420

(22) Filed: Feb. 3, 2026

(30) Foreign Application Priority Data
Apr. 4, 2025 (KR) 10-2025-0043844

(51) Int. Cl. G09G 3/3233; H10K 59/131

(52) U.S. Cl. CPC G09G 3/3233; H10K 59/131; G09G 2300/0426; G09G 2300/0819; G09G 2300/0842; G09G 2300/0861

(57) ABSTRACT

A display device includes: a substrate including a first pixel circuit area and a second pixel circuit area located in a first direction from the first pixel circuit area; a first driving transistor and a second driving transistor respectively located in the first and second pixel circuit areas and configured to generate a driving current; a first data write transistor in the first pixel circuit area and configured to operate in response to a first write gate signal; a second data write transistor in the second pixel circuit area and configured to operate in response to a second write gate signal; a first write gate line in the first and second pixel circuit areas, extending in the first direction, and connected to a gate electrode of the first data write transistor; a second write gate line in the first and second pixel circuit areas, extending in the first direction.

### CROSS-REFERENCE TO RELATED APPLICATION

The present application claims priority to and the benefit of Korean Patent Application No. 10-2025-0043844, filed on Apr. 4, 2025, in the Korean Intellectual Property Office, the entire disclosure of which is incorporated by reference herein.

### BACKGROUND

### 1. Field

Embodiments provide generally to a display device and an electronic device including the same. More particularly, embodiments relate to a display device that provides visual information and the electronic device including the same.

### 2. Description of the Related Art

As information technology develops, the importance of display devices, which are communication media between users and information, is being highlighted. Accordingly, the use of display devices such as a liquid crystal display device, an organic light emitting display device, a plasma display device, and/or the like is increasing.

Recently, display devices using high-resolution micro OLEDs are being manufactured. The high-resolution micro OLEDs may be OLEDos (organic light-emitting diodes on silicon) formed using a semiconductor process based on a silicon wafer.

### SUMMARY

Embodiments provide a display device with enhanced driving capability.

Embodiments provide an electronic device including the display device.

According to one or more embodiments of the present disclosure, a display device includes: a substrate including a first pixel circuit area and a second

pixel circuit area located in a first direction from the first pixel circuit area; a first driving transistor and a second driving transistor respectively located in the first and second pixel circuit areas and configured to generate a driving current; a first data write transistor in the first pixel circuit area and configured to operate in response to a first write gate signal; a second data write transistor in the second pixel circuit area and configured to operate in response to a second write gate signal; a first write gate line in the first and second pixel circuit areas, extending in the first direction, and connected to a gate electrode of the first data write transistor; a second write gate line in the first and second pixel circuit areas, extending in the first direction, adjacent to the first write gate line in a second direction crossing the first direction, and connected to a gate electrode of the second data write transistor; a first light-emitting element electrically connected to the first driving transistor; and a second light-emitting element electrically connected to the second driving transistor.

In one or more embodiments, the first data write transistor is configured to receive a first data voltage or a first reference voltage having a voltage level different from the first data voltage, and wherein the second data write transistor is configured to receive a second data voltage or a second reference voltage having a voltage level different from the second data voltage.

In one or more embodiments, the display device further includes: a first operation control transistor adjacent to the first data write transistor in the second direction in the first pixel circuit area and configured to receive a driving voltage in response to a first emission control signal; a second operation control transistor adjacent to the second data write transistor in the second direction in the second pixel circuit area and configured to receive a driving voltage in response to a second emission control signal; a second emission control line in the first and second pixel circuit areas, adjacent to the second write gate line in the second direction, and connected to a gate electrode of the second operation control transistor; and a first emission control line in the first and second pixel circuit areas, adjacent to the second emission control line in the second direction, and connected to a gate electrode of the first operation control transistor.

In one or more embodiments, a center of a channel region of the first data write transistor coincides with a virtual first line extending in the first direction, and a center of a channel region of the second data write transistor coincides with a virtual second line which is parallel to the virtual first line and does not overlap the virtual first line, and wherein a center of a channel region of the first operation control transistor coincides with a virtual third line which is parallel to the virtual first line and a center of a channel region of the second operation control transistor coincides with a virtual fourth line which is parallel to the virtual first line and does not overlap the virtual second line.

In one or more embodiments, the display device further comprising: a first source connection electrode connected to a source region of the first data write transistor; a first drain connection electrode connected to a drain region of the first data write transistor; a second source connection electrode connected to a source region of the second data write transistor; and a second drain connection electrode connected to a drain region of the second data write transistor, wherein the first source connection electrode has a planar shape which is symmetrical with respect to a planar shape of the second source connection electrode with respect to an axis extending in the first direction, and the second drain connection electrode has a planar shape which is symmetrical with respect to a planar shape of the first drain connection electrode with respect to the axis.

In one or more embodiments, the first and second source connection electrodes and the first and second drain connection electrodes are located in a same layer as the first and second write gate lines.

In one or more embodiments, the display device further comprising: a third source connection electrode connected to a source region of the first operation control transistor; a third drain connection electrode connected to a drain region of the first operation control transistor; a fourth source connection electrode connected to a source region of the second operation control transistor; and a fourth drain connection electrode connected to a drain region of the second operation control transistor, wherein the third source connection electrode has a planar shape which is symmetrical with respect to a planar shape of the fourth source connection electrode with respect to an axis extending in the first direction, and the third drain connection electrode has a planar shape which is symmetrical with respect to a planar shape of the fourth drain connection electrode with respect to the axis.

In one or more embodiments, the third and fourth source connection electrodes and the third and fourth drain connection electrodes are located in a same layer as the first and second emission control lines.

In one or more embodiments, the first write gate line comprises a first-first protrusion and a first-second protrusion protruding in the second direction, wherein the second write gate line comprises a second-first protrusion and a second-second protrusion protruding in a direction opposite to the second direction, and wherein the first-first protrusion and the second-first protrusion are in the first pixel circuit area, and the first-second protrusion and the second-second protrusion are in the second pixel circuit area.

In one or more embodiments, a width of the first-first protrusion in the first direction is different from a width of the first-second protrusion in the first direction, and wherein a width of the second-first protrusion in the first direction is different from a width of the second-second protrusion in the first direction.

In one or more embodiments, the first write gate line comprises a first shield portion protruding between the first data write transistor and another data write transistor adjacent to the first data write transistor from the first-first protrusion along the second direction, and wherein the second write gate line comprises a second shield portion protruding between the first and second data write transistors from the second-second protrusion along a direction opposite to the second direction.

In one or more embodiments, the first emission control line comprises a third-first protrusion and a third-second protrusion protruding in a direction opposite to the second direction, wherein the second emission control line comprises a fourth-first protrusion and a fourth-second protrusion protruding in the second direction, and wherein the third-first protrusion and the fourth-first protrusion are in the first pixel circuit area, and the third-second protrusion and the fourth-second protrusion are in the second pixel circuit area.

In one or more embodiments, a width of the third-first protrusion in the first direction is different from a width of the third-second protrusion in the first direction, and wherein a width of the fourth-first protrusion in the first direction is different from a width of the fourth-second protrusion in the first direction.

In one or more embodiments, the display device further comprising: a first emission control transistor adjacent to the first driving transistor in the second direction in the first pixel circuit area and connected to the first driving transistor; a second emission control transistor adjacent to the second driving transistor in the second direction in the second pixel circuit area and connected to the second driving transistor; a first initialization transistor adjacent to the first emission control transistor in the second direction in the first pixel circuit area and connected to the first emission control transistor and the first light-emitting element; and a second initialization transistor adjacent to the second emission control transistor in the second direction in the second pixel circuit area and connected to the second emission control transistor and the second light-emitting element.

In one or more embodiments, a display device comprising: a substrate including a first pixel circuit area, a second pixel circuit area, a third pixel circuit area, and a fourth pixel circuit area arranged sequentially along a first direction; a first driving transistor, a second driving transistor, a third driving transistor, and a fourth driving transistor which are respectively disposed in the first, second, third, and fourth pixel circuit areas and configured to generate a driving current; a first data write transistor which is located in the first pixel circuit area and configured to operate in response to a first write gate signal; a second data write transistor which is located in the second pixel circuit area and configured to operate in response to a second write gate signal; a third data write transistor which is located in the third pixel circuit area and configured to operate in response to a third write gate signal; a fourth data write transistor which is located in the fourth pixel circuit area and configured to operate in response to a fourth write gate signal; a first write gate line located in the first, second, third, and fourth pixel circuit areas, extending in the first direction, and connected to a gate electrode of the first data write transistor and a gate electrode of the third data write transistor; a second write gate line located in the first, second, third, and fourth pixel circuit areas, extending in the first direction, adjacent to the first write gate line in a second direction intersecting the first direction, and connected to a gate electrode of the second data write transistor and a gate electrode of the fourth data write transistor; and a first light-emitting element, a second light-emitting element, a third light-emitting element, and a fourth light-emitting element electrically connected to the first, second, third, and fourth driving transistors, respectively.

In one or more embodiments, the display device further comprising: a first operation control transistor which is adjacent to the first data write transistor in the second direction in the first pixel circuit area and configured to receive a driving voltage in response to a first emission control signal; a second operation control transistor which is adjacent to the second data write transistor in the second direction in the second pixel circuit area and configured to receive the driving voltage in response to a second emission control signal; a third operation control transistor which is adjacent to the third data write transistor in the second direction in the third pixel circuit area and configured to receive the driving voltage in response to the first emission control signal; a fourth operation control transistor which is adjacent to the fourth data write transistor in the second direction in the fourth pixel circuit area and configured to receive the driving voltage in response to the second emission control signal; a second emission control line located in the first, second, third, and fourth pixel circuit areas, extending in the first direction, adjacent to the second write gate line in the second direction, and connected to a gate electrode of the second operation control transistor and a gate electrode of the fourth operation control transistor; and a first emission control line located in the first, second, third, and fourth pixel circuit areas, extending in the first direction, adjacent to the second emission control line in the second direction, and connected to a gate electrode of the first operation control transistor and a gate electrode of the third operation control transistor.

In one or more embodiments, an electronic device comprising: a display device; and a processor which provides input image data and control signal to the display device to control the display device, wherein the display device comprises: a substrate including a first pixel circuit area and a second pixel circuit area located in a first direction from the first pixel circuit area; a first driving transistor and a second driving transistor which are respectively disposed in the first and second pixel circuit areas and configured to generate a driving current; a first data write transistor which is located in the first pixel circuit area and configured to operate in response to a first write gate signal; a second data write transistor which is located in the second pixel circuit area and configured to operate in response to a second write gate signal; a first write gate line located in the first and second pixel circuit areas, extending in the first direction, and connected to a gate electrode of the first data write transistor; a second write gate line located in the first and second pixel circuit areas, extending in the first direction, adjacent to the first write gate line in a second direction intersecting the first direction, and connected to a gate electrode of the second data write transistor; a first light-emitting element electrically connected to the first driving transistor; and a second light-emitting element electrically connected to the second driving transistor.

In one or more embodiments, the display device further comprises: a first operation control transistor which is adjacent to the first data write transistor in the second direction in the first pixel circuit area and configured to receive a driving voltage in response to a first emission control signal; a second operation control transistor which is adjacent to the second data write transistor in the second direction in the second pixel circuit area and configured to receive a driving voltage in response to a second emission control signal; a second emission control line in the first and second pixel circuit areas, adjacent to the second write gate line in the second direction, and connected to a gate electrode of the second operation control transistor; and a first emission control line in the first and second pixel circuit areas, adjacent to the second emission control line in the second direction, and connected to a gate electrode of the first operation control transistor.

In one or more embodiments, the display device further comprises: a first source connection electrode connected to a source region of the first data write transistor; a first drain connection electrode connected to a drain region of the first data write transistor; a second source connection electrode connected to a source region of the second data write transistor; and a second drain connection electrode connected to a drain region of the second data write transistor, wherein the first source connection electrode has a planar shape which is symmetrical with respect to a planar shape of the second source connection electrode with respect to an axis extending in the first direction, and the second drain connection electrode has a planar shape which is symmetrical with respect to a planar shape of the first drain connection electrode with respect to the axis.

In one or more embodiments, the display device further comprises: a third source connection electrode connected to a source region of the first operation control transistor; a third drain connection electrode connected to a drain region of the first operation control transistor; a fourth source connection electrode connected to a source region of the second operation control transistor; and a fourth drain connection electrode connected to a drain region of the second operation control transistor, wherein the third source connection electrode has a planar shape which is symmetrical with respect to a planar shape of the fourth source connection electrode with respect to an axis extending in the first direction, and the third drain connection electrode has a planar shape which is symmetrical with respect to a planar shape of the fourth drain connection electrode with respect to the axis.

In a display device according to embodiments of the present disclosure, the number of the write gate lines disposed in one pixel circuit area may be two and the number of the emission control lines disposed in one pixel circuit area may be two. The two write gate lines may be alternately connected to pixel driving circuit parts of even-numbered columns and pixel driving circuit parts of odd-numbered columns, or alternately connected to every three adjacent pixel driving circuit parts. The two emission control lines may be alternately connected to the pixel driving circuit parts of even-numbered columns and the pixel driving circuit parts of odd-numbered columns, or alternately connected to every three adjacent pixel driving circuit parts. Accordingly, the load variation of the write gate lines may be minimized and the load variation of the emission control lines may be minimized. In this case, the driving capability of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to one or more embodiments of the present disclosure.

FIG. 2 is a block diagram schematically illustrating the display device of FIG. 1.

FIG. 3 is a circuit diagram illustrating a circuit structure of a first pixel and a second pixel of FIG. 1 and FIG. 2.

FIG. 4 is a cross-sectional view schematically illustrating a display panel of FIGS. 1 and 2.

FIG. 5 is a cross-sectional view illustrating one transistor included in a transistor substrate of FIG. 4.

FIG. 6 is a plan view illustrating a transistor substrate of FIG. 4.

FIGS. 7, 8, and 9 are layout views illustrating an example of first, second, third, fourth, fifth, and sixth pixel driving circuit parts included in the transistor substrate of FIG. 6.

FIG. 10 is a layout view illustrating a metal layer disposed on the first, second, third, fourth, fifth, and sixth pixel driving circuit parts of FIG. 9.

FIG. 11 is an enlarged layout view of an area A of FIG. 10.

FIG. 12 is a layout view illustrating another example of first, second, third, fourth, fifth, and sixth pixel driving circuit parts included in the transistor substrate of FIG. 6.

FIG. 13 is a layout view illustrating a metal layer disposed on the first, second, third, fourth, fifth, and sixth pixel driving circuit parts of FIG. 12.

FIG. 14 is an enlarged layout view of an area B of FIG. 13.

FIG. 15 is a block diagram illustrating an electronic device according to one or more embodiments of the present disclosure.

FIG. 16 is a schematic diagram illustrating an electronic device according to various embodiments.

### DETAILED DESCRIPTION

Hereinafter, a display device and an electronic device including the same according to one or more embodiments of the present disclosure will be explained in detail with reference to the accompanying drawings. The same reference numerals are used for the same components in the drawings, and redundant descriptions of the same components will be omitted.

In the present disclosure, a plane may be defined along a first direction D1 and a second direction D2 intersecting the first direction D1. For example, the first direction D1 and the second direction D2 may be perpendicular to each other. In addition, a third direction D3 may be perpendicular to the plane.

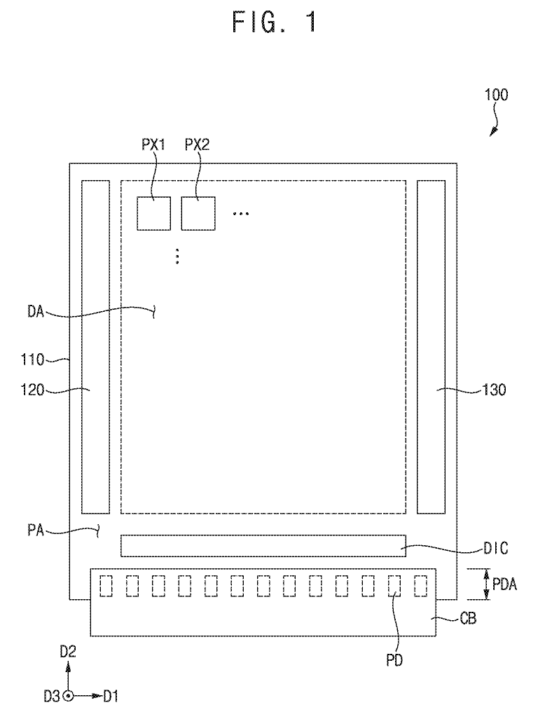

FIG. 1 is a plan view illustrating a display device according to one or more embodiments of the present disclosure.

Referring to FIG. 1, a display device 100 according to one or more embodiments of the present disclosure may include a display panel 110, a driver integrated circuit DIC, and a circuit board CB.

The display device 100 may have a rectangular planar shape (e.g., a rectangle with rounded corners). However, the present disclosure is not necessarily limited thereto, and the display device 100 may have various planar shapes.

The display panel 110 may include a display area DA and a peripheral area PA. The display area DA may be an area that generates light or displays an image by adjusting the transmittance of light provided from an external light source. The peripheral area PA may be an area that does not display an image. The peripheral area PA may be located around the display area DA along an edge or a periphery of the display area DA. For example, the peripheral area PA may entirely surround the display area DA.

The display panel 110 may include a plurality of pixels PX1 and PX2 arranged in the display area DA. The pixels PX1 and PX2 may be arranged in a matrix form along the first direction D1 and the second direction D2. However, the present disclosure is not necessarily limited thereto, and the pixels PX1 and PX2 may be arranged in various forms.

Each of the pixels PX1 and PX2 may include a driving element (e.g., a transistor) for generating a driving current and a light-emitting element that is electrically connected to the driving element and generates light based on the driving current. Accordingly, the pixels PX1 and PX2 may emit light according to the driving current. By emitting light, the pixels PX1 and PX2 enable the display area DA to display an image.

The pixels PX1 and PX2 may include a first pixel PX1 and a second pixel PX2. For example, the first pixel PX1 and the second pixel PX2 may emit light of the same color (e.g., white light). Alternatively, the first pixel PX1 and the second pixel PX2 may emit light of different colors. That is, the first pixel PX1 may emit light of a first color, and the second pixel PX2 may emit light of a second color different from the first color. For example, each of the first color and the second color may be red, green, or blue.

Lines connected to the pixels PX1 and PX2 may be disposed in the display area DA. For example, the lines may include a data line, a gate line, and an emission control line.

Drivers for driving the pixels PX1 and PX2 may be disposed in the peripheral area PA. For example, the drivers may include a gate driver 120 and an emission driver 130. The gate driver 120 may be disposed in the peripheral area PA adjacent to a left side of the display area DA, and the emission driver 130 may be disposed in the peripheral area PA adjacent to a right side of the display area DA. The pixels PX1 and PX2 may emit light based on signals provided from the drivers.

The peripheral area PA may include a pad area PDA. The pad area PDA may be located on one side of the display area DA and may extend in the first direction D1.

The driver integrated circuit DIC may be bonded to the pad area PDA on the display panel 110. Accordingly, the driver integrated circuit DIC may be electrically connected to the display panel 110.

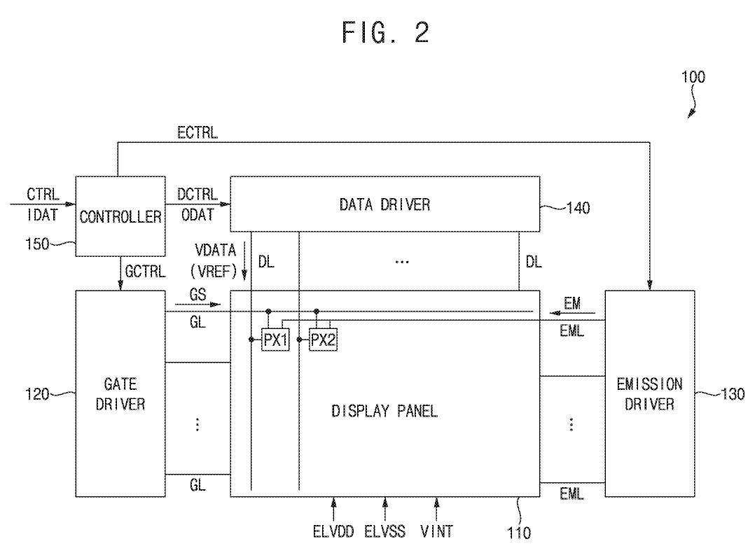

The driver integrated circuit DIC may convert digital data signals among driving signals into analog data signals and provide the analog data signals to the pixels PX1 and PX2. For example, the driver integrated circuit DIC may be a data driver (e.g., 140 of FIG. 2).

The display panel 110 may include a plurality of pads PD disposed in the pad area PDA. The pads PD may be spaced (e.g., spaced apart) from each other along the first direction D1. For example, the pads PD may include metals, alloys, metal nitrides, conductive metal oxides, transparent conductive materials, and/or the like. These materials may be used alone or in combination with each other.

One end of the circuit board CB may be bonded to the pads PD disposed in the pad area PDA. Accordingly, the circuit board CB may be electrically connected to the display panel 110. The other end of the circuit board CB may be electrically connected to an external device. Signals, voltages, and/or the like generated by the external device may be supplied to driver integrated circuit DIC and the pixels PX1 and PX2 through the circuit board CB. For example, the circuit board CB may be a flexible printed circuit board (FPCB), a printed circuit board (PCB), or a flexible flat cable (FFC).

Although FIG. 1 illustrates the driver integrated circuit DIC mounted by a chip on plastic (COP) method or a chip on glass (COG) method, the present disclosure is not necessarily limited thereto. For example, the driver integrated circuit DIC may be mounted using a chip on film (COF) method.

FIG. 2 is a block diagram schematically illustrating the display device of FIG. 1.

Referring to FIG. 2, a display device 100 according to one or more embodiments of the present disclosure may include a display panel 110, a gate driver 120, an emission driver 130, a data driver 140, and a controller 150.

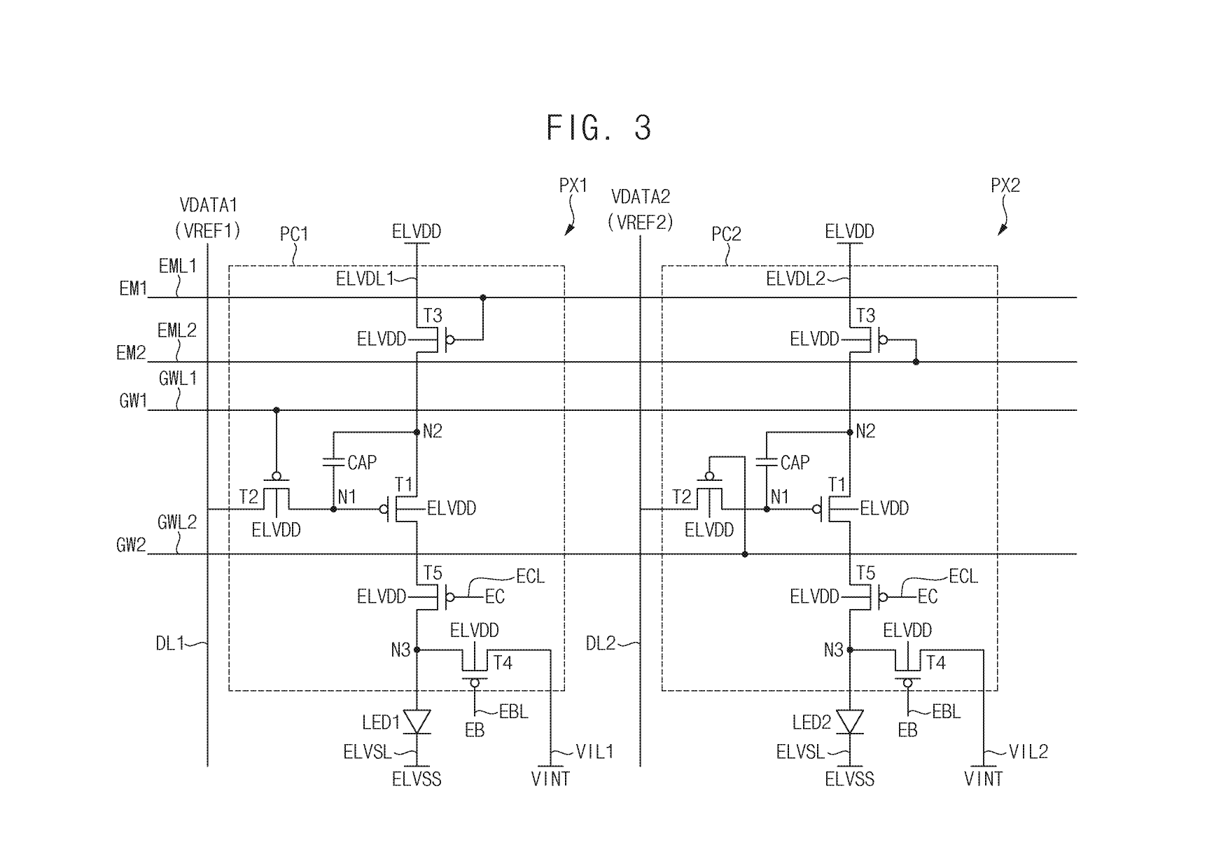

The display panel 110 may include a plurality of gate lines GL, a plurality of data lines DL, a plurality of emission control lines EML, and a plurality of pixels PX1 and PX2. The gate lines GL, the emission control lines EML, and the data lines DL may be electrically connected to the pixels PX1 and PX2. The gate lines GL may receive a gate signal GS, the emission control lines EML may receive an emission control signal EM, and the data lines DL may receive a data voltage VDATA or a reference voltage VREF. For example, the gate signal GS may include gate signals GW1, GW2, EB, and EC of FIG. 3, the emission control signal EM may include emission control signals EM1 and EM2 of FIG. 3, the data voltage VDATA may include data voltages VDATA1 and VDATA2 of FIG. 3, and the reference voltage VREF may include reference voltages VREF1 and VREF2 of FIG. 3.

Each of the gate lines GL may extend in a first direction D1 (e.g., a row direction). Each of the emission control lines EML may extend in the first direction D1. Each of the data lines DL may extend in a second direction D2 (e.g., a column direction) intersecting the first direction D1. The gate lines GL, the emission control lines EML, and the data lines DL may be insulated from each other. The pixels PX1 and PX2 may be arranged in an area where the gate lines GL (or the emission control lines EML) cross the data lines DL.

In one or more embodiments, each of the pixels PX1 and PX2 may include a switching transistor that provides the data voltage VDATA in response to the gate signal GS, a storage capacitor that stores the data voltage VDATA provided by the switching transistor, a driving transistor that generates a driving current based on the data voltage VDATA stored in the storage capacitor; and a light-emitting element that emits light based on the driving current generated by the driving transistor. For example, the light-emitting element may include a light-emitting diode (LED), an organic light-emitting diode (OLED), or a quantum dot (QD) light-emitting element.

The pixels PX1 and PX2 may receive a driving voltage ELVDD and a common voltage ELVSS. The pixels PX1 and PX2 may receive the data voltage VDATA in response to the gate signal GS and the emission control signal EM, and may generate grayscale light corresponding to the data voltage VDATA using the driving voltage ELVDD and the common voltage ELVSS. In addition, the pixels PX1 and PX2 may further receive an initialization voltage VINT.

The gate driver 120 may provide the gate signals GS to the pixels PX1 and PX2 through the gate lines GL based on a gate control signal GCTRL received from the controller 150. In one or more embodiments, the gate driver 120 may sequentially provide the gate signals GS to the pixels PX1 and PX2 in units of rows. The gate control signal GCTRL may include a gate start signal, a gate clock signal, and/or the like, but the present disclosure is not necessarily limited thereto. For example, the gate driver 120 may be integrated or formed in a periphery of the display panel 110. Alternatively, the gate driver 120 may be implemented with one or more integrated circuits (ICs).

The emission driver 130 may provide the emission control signals EM to the pixels PX1 and PX2 through the emission control lines EML based on an emission control signal ECTRL received from the controller 150. In one or more embodiments, the emission driver 130 may sequentially provide the emission control signals EM to the pixels PX1 and PX2 in units of rows. The emission control signal ECTRL may include an emission start signal, an emission clock signal, and/or the like, but the present disclosure is not necessarily limited thereto. For example, the emission driver 130 may be integrated or formed in the periphery of the display panel 110. Alternatively, the emission driver 130 may be implemented with one or more integrated circuits (ICs).

The data driver 140 may receive a data control signal DCTRL and an output image data ODAT from the controller 150, and may provide the data voltages VDATA to the pixels PX1 and PX2 through the data lines DL based on the data control signal DCTRL and the output image data ODAT. The data control signal DCTRL may include an output data enable signal, a horizontal start signal, a load signal, and/or the like, but the present disclosure is not necessarily limited thereto. For example, the data driver 140 may be implemented as a single integrated circuit, which may be referred to as a timing controller embedded data driver (TED). Alternatively, the data driver 140 may be implemented with separate integrated circuits.

The controller 150 may receive an input image data IDAT and a control signal CTRL from an external host processor. For example, the controller 150 may be a timing controller, and the host processor may include at least one of a central processing unit (CPU), an application processor (AP), a graphic processing unit (GPU), a communication processor (CP), or an image signal processor (ISP). In one or more embodiments, the input image data IDAT may be RGB image data including red, green, and blue image data. The control signal CTRL may include a vertical sync signal, a horizontal sync signal, an input data enable signal, a master clock signal, and/or the like, but the present disclosure is not necessarily limited thereto.

The controller 150 may generate the gate control signal GCTRL, the emission control signal ECTRL, the data control signal DCTRL, and the output image data ODAT based on the input image data IDAT and the control signal CTRL. The controller 150 may provide the gate control signal GCTRL to the gate driver 120 to control the operation of the gate driver 120. The controller 150 may provide the emission control signal ECTRL to the emission driver 130 to control operation of the emission driver 130. In addition, the controller 150 may provide the output image data ODAT and the data control signal DCTRL to the data driver 140 to control the operation of the data driver 140. That is, the controller 150 may control the driving of the display panel 110 based on the input image data IDAT and the control signal CTRL.

FIG. 3 is a circuit diagram illustrating a circuit structure of a first pixel and a second pixel of FIG. 1 and FIG. 2.

Referring to FIG. 3, the first pixel PX1 may include a first pixel driving circuit part PC1 and a first light-emitting element LED1 electrically connected to the first pixel driving circuit part PC1. The first pixel driving circuit part PC1 may generate a driving current, and the first light-emitting element LED1 may generate light based on the driving current. Likewise, the second pixel PX2 may include a second pixel driving circuit part PC2 and a second light-emitting element LED2 electrically connected to the second pixel driving circuit part PC2. The second pixel driving circuit part PC2 may generate a driving current, and the second light-emitting element LED2 may generate light based on the driving current.

Each of the first pixel driving circuit part PC1 and the second pixel driving circuit part PC2 may include a first transistor T1, a second transistor T2, a third transistor T3, a fourth transistor T4, a fifth transistor T5, and a capacitor CAP.

In one or more embodiments, the first transistor T1, the second transistor T2, the third transistor T3, the fourth transistor T4, and the fifth transistor T5 may all be PMOS transistors. However, the present disclosure is not necessarily limited thereto, and some of the first transistor T1, the second transistor T2, the third transistor T3, the fourth transistor T4, and the fifth transistor T5 may be NMOS transistors, and the rest may be PMOS transistors.

In one or more embodiments, the first transistor T1, the second transistor T2, the third transistor T3, the fourth transistor T4, and the fifth transistor T5 may be MOSFETs (metal-oxide-semiconductor field-effect transistors) formed by semiconductor processes. That is, the first transistor T1, the second transistor T2, the third transistor T3, the fourth transistor T4, and the fifth transistor T5 may be formed on a silicon wafer substrate.

The first transistor T1 may include a gate electrode, a first electrode, and a second electrode. The gate electrode of the first transistor T1 may be connected to a first node N1. The first electrode of the first transistor T1 may be connected to a second node N2. The second electrode of the first transistor T1 may be connected to the first electrode of the fifth transistor T5. The first transistor T1 may provide the driving current to the light-emitting element LED. The first transistor T1 may be referred to as a driving transistor.

The first transistor T1 may further include a body electrode. The body electrode of the first transistor T1 may receive a driving voltage ELVDD. For example, a driving voltage line (e.g., ELVDL1 or ELVDL2), which receives the driving voltage ELVDD, may be connected to the body electrode of the first transistor T1. Alternatively, a voltage other than the driving voltage ELVDD may be applied to the body electrode of the first transistor T1.

The second transistor T2 may include a gate electrode, a first electrode, and a second electrode. The second electrode of the second transistor T2 may be connected to the first node N1. In one or more embodiments, the first pixel driving circuit part PC1 and the second pixel driving circuit part PC2 may receive different write gate signals through different write gate lines, and may receive different voltages through different data lines. For example, in the first pixel driving circuit part PC1, the gate electrode of the second transistor T2 may be connected to a first write gate line GWL1 that receives a first write gate signal GW1, and the first electrode of the second transistor T2 may be connected to a first data line DL1 that receives a first data voltage VDATA1 or a first reference voltage VREF1. In the second pixel driving circuit part PC2, the gate electrode of the second transistor T2 may be connected to a second write gate line GWL2 that receives a second write gate signal GW2, and the first electrode of the second transistor T2 may be connected to a second data line DL2 that receives a second data voltage VDATA2 or a second reference voltage VREF2. The second transistor T2 may be referred to as a data write transistor.

For example, the voltage level of the first reference voltage VREF1 may be lower than the voltage level of the first data voltage VDATA1, and the voltage level of the second reference voltage VREF2 may be lower than the voltage level of the second data voltage VDATA2.

The second transistor T2 may further include a body electrode. The body electrode of the second transistor T2 may receive the driving voltage ELVDD. For example, a driving voltage line (e.g., ELVDL1 or ELVDL2), which receives the driving voltage ELVDD, may be connected to the body electrode of the second transistor T2.

Alternatively, a voltage different from the driving voltage ELVDD may be applied to the body electrode of the second transistor T2.

The second transistor T2 may be turned on or off in response to the write gate signals GW1 and GW2. For example, in case that the write gate signals GW1 and GW2 has an active level, the second transistor T2 may be turned on. In this case, the second transistor T2 may provide the data voltages VDATA1 and VDATA2 or the reference voltages VREF1 and VREF2 to the first node N1. Conversely, in case that the write gate signals GW1 and GW2 has an inactive level, the second transistor T2 may be turned off. In this case, the second transistor T2 may block the supply of the data voltages VDATA1 and VDATA2 and the reference voltages VREF1 and VREF2. In case that the second transistor T2 provides the reference voltages VREF1 and VREF2 to the first node N1, the first node N1 may be initialized.

For example, in case that the first write gate signal GW1 has an active level and the second write gate signal GW2 has an inactive level, the second transistor T2 of the first pixel driving circuit part PC1 may be turned on, and the second transistor T2 of the second pixel driving circuit part PC2 may be turned off. In this case, the second transistor T2 of the first pixel driving circuit part PC1 may provide the first data voltage VDATA1 or the first reference voltage VREF1 to the first node N1, and the second transistor T2 of the second pixel driving circuit part PC2 may block the supply of the second data voltage VDATA2 and the second reference voltage VREF2.

For example, in case that the first write gate signal GW1 has an inactive level and the second write gate signal GW2 has an active level, the second transistor T2 of the first pixel driving circuit part PC1 may be turned off, and the second transistor T2 of the second pixel driving circuit part PC2 may be turned on. In this case, the second transistor T2 of the first pixel driving circuit part PC1 may block the supply of the first data voltage VDATA1 and the first reference voltage VREF1, and the second transistor T2 of the second pixel driving circuit part PC2 may provide the second data voltage VDATA2 or the second reference voltage VREF2 to the first node N1.

For example, in case that the first write gate signal GW1 has an active level and the second write gate signal GW2 has an active level, the second transistor T2 of the first pixel driving circuit part PC1 may be turned on, and the second transistor T2 of the second pixel driving circuit part PC2 may be turned on. In this case, the second transistor T2 of the first pixel driving circuit part PC1 may provide the first data voltage VDATA1 to the first node N1, and the second transistor T2 of the second pixel driving circuit part PC2 may provide the second reference voltage VREF2 to the first node N1. Alternatively, the second transistor T2 of the first pixel driving circuit part PC1 may provide the first reference voltage VREF1 to the first node N1, and the second transistor T2 of the second pixel driving circuit part PC2 may provide the second data voltage VDATA2 to the first node N1.

The third transistor T3 may include a gate electrode, a first electrode, and a second electrode. The second electrode of the third transistor T3 may be connected to the second node N2. In one or more embodiments, the first pixel driving circuit part PC1 and the second pixel driving circuit part PC2 may receive different emission control signals through different emission control lines and may receive the driving voltage ELVDD through different driving voltage lines. For example, in the first pixel driving circuit part PC1, the gate electrode of the third transistor T3 may be connected to a first emission control line EML1 that receives a first emission control signal EM1, and the first electrode of the third transistor T3 may be connected to a first driving voltage line ELVDL1 that receives the driving voltage ELVDD. In the second pixel driving circuit part PC2, the gate electrode of the third transistor T3 may be connected to a second emission control line EML2 that receives a second emission control signal EM2, and the first electrode of the third transistor T3 may be connected to a second driving voltage line ELVDL2 that receives the driving voltage ELVDD. The third transistor T3 may be referred to as an operation control transistor.

The third transistor T3 may further include a body electrode. The driving voltage ELVDD may be applied to the body electrode of the third transistor T3. For example, the body electrode of the third transistor T3 may be connected to a driving voltage line (e.g., ELVDL1 or ELVDL2), which receives the driving voltage ELVDD. Alternatively, a voltage other than the driving voltage ELVDD may be applied to the body electrode of the third transistor T3.

The third transistor T3 may be turned on or off in response to the emission control signals EM1 and EM2. For example, in case that the emission control signals EM1 and EM2 has an active level, the third transistor T3 may be turned on. In this case, the third transistor T3 may provide the driving voltage ELVDD to the second node N2. Conversely, in case that the emission control signals EM1 and EM2 has an inactive level, the third transistor T3 may be turned off. In this case, the third transistor T3 may block the supply of the driving voltage ELVDD.

For example, in case that the first emission control signal EM1 has an active level and the second emission control signal EM2 has an inactive level, the third transistor T3 of the first pixel driving circuit part PC1 may be turned on, and the third transistor T3 of the second pixel driving circuit part PC2 may be turned off. In this case, the third transistor T3 of the first pixel driving circuit part PC1 may provide the driving voltage ELVDD to the second node N2, and the third transistor T3 of the second pixel driving circuit part PC2 may block the supply of the driving voltage ELVDD.

For example, in case that the first emission control signal EM1 has an inactive level and the second emission control signal EM2 has an active level, the third transistor T3 of the first pixel driving circuit part PC1 may be turned off, and the third transistor T3 of the second pixel driving circuit part PC2 may be turned on. In this case, the third transistor T3 of the first pixel driving circuit part PC1 may block the supply of the driving voltage ELVDD, and the third transistor T3 of the second pixel driving circuit part PC2 may provide the driving voltage ELVDD to the second node N2.

For example, in case that the first emission control signal EM1 has an active level and the second emission control signal EM2 has an active level, the third transistors T3 of the first pixel driving circuit part PC1 may be turned on and the third transistors T3 of the second pixel driving circuit part PC2 may be turned on. In this case, the third transistor T3 of the first pixel driving circuit part PC1 may provide the driving voltage ELVDD to the second node N2, and the third transistor T3 of the second pixel driving circuit part PC2 may provide the driving voltage ELVDD to the second node N2.

The fourth transistor T4 may include a gate electrode, a first electrode, and a second electrode. The gate electrode of the fourth transistor T4 may be connected to an initialization gate line EBL, which receives an anode initialization gate signal EB. In the first pixel driving circuit part PC1, the first electrode of the fourth transistor T4 may be connected to a first initialization line VIL1, which receives an initialization voltage VINT. In the second pixel driving circuit part PC2, the first electrode of the fourth transistor T4 may be connected to a second initialization line VIL2, which receives the initialization voltage VINT. The second electrode of the fourth transistor T4 may be connected to a third node N3. The fourth transistor T4 may be referred to as an initialization transistor.

The fourth transistor T4 may further include a body electrode. The body electrode of the fourth transistor T4 may receive the driving voltage ELVDD. For example, the body electrode of the fourth transistor T4 may be connected to a driving voltage line (e.g., ELVDL1 or ELVDL2), which receives the driving voltage ELVDD. Alternatively, a voltage other than the driving voltage ELVDD may be applied to the body electrode of the fourth transistor T4.

The fourth transistor T4 may be turned on or off in response to the anode initialization gate signal EB. For example, in case that the anode initialization gate signal EB has an active level, the fourth transistor T4 may be turned on. In this case, the fourth transistor T4 may provide the initialization voltage VINT to the third node N3. Conversely, in case that the anode initialization gate signal EB has an inactive level, the fourth transistor T4 may be turned off. In this case, the fourth transistor T4 may block the supply of the initialization voltage VINT.

The fifth transistor T5 may include a gate electrode, a first electrode, and a second electrode. The gate electrode of the fifth transistor T5 may be connected to an emission control line ECL which receives an emission control signal EC. The first electrode of the fifth transistor T5 may be connected to the second electrode of the first transistor T1. The second electrode of the fifth transistor T5 may be connected to the third node N3. The fifth transistor T5 may be referred to as an emission control transistor.

The fifth transistor T5 may further include a body electrode. The body electrode of the fifth transistor T5 may receive the driving voltage ELVDD. For example, the body electrode of the fifth transistor T5 may be connected to the driving voltage line (e.g., ELVDL1 or ELVDL2), which receives the driving voltage ELVDD. Alternatively, a voltage different from the driving voltage ELVDD may be applied to the body electrode of the fifth transistor T5.

The fifth transistor T5 may be turned on or off in response to the emission control signal EC. For example, in case that the emission control signal EC has an active level, the fifth transistor T5 may be turned on. In this case, the fifth transistor T5 may provide the driving current generated by the first transistor T1 to the third node N3. Conversely, in case that the emission control signal EC has an inactive level, the fifth transistor T5 may be turned off. In this case, the fifth transistor T5 may block the supply of the driving current generated by the first transistor T1.

In one or more embodiments, the first electrode of each of the first, second, third, fourth, and fifth transistors T1, T2, T3, T4, and T5 may be a source electrode, and the second electrode of each of the first, second, third, fourth, and fifth transistors T1, T2, T3, T4, and T5 may be a drain electrode. However, the present disclosure is not necessarily limited thereto.

The capacitor CAP may include a first electrode and a second electrode. The first electrode of the capacitor CAP may be connected to the first node N1. The second electrode of the capacitor CAP may be connected to the second node N2. The capacitor CAP may store a differential voltage between the gate voltage and the source voltage of the first transistor T1.

Each of the first light-emitting element LED1 and the second light-emitting element LED2 may include an anode electrode and a cathode electrode. The anode electrodes of the first light-emitting element LED1 and the second light-emitting element LED2 may be connected to the third node N3. The cathode electrode of the first light-emitting element LED1 and the second light-emitting element LED2 may be connected to a common voltage line ELVSL, which receives the common voltage ELVSS. The common voltage ELVSS may have a voltage level lower than a voltage level of the driving voltage ELVDD.

Although FIG. 3 illustrates an example in which one pixel driving circuit part PC1 or PC2 includes five transistors and one capacitor, the present disclosure is not necessarily limited thereto.

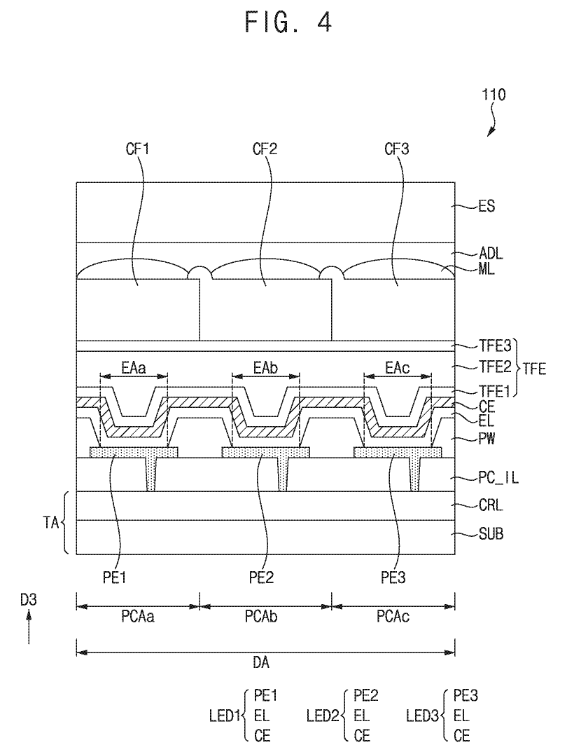

FIG. 4 is a cross-sectional view schematically illustrating a display panel of FIGS. 1 and 2.

Referring to FIG. 4, a display panel 110 included in the display device 100 according to one or more embodiments of the present disclosure may include a transistor substrate TA, a circuit insulating layer PC_IL, first, second, and third light-emitting elements LED1, LED2, and LED3, a partition wall PW, an encapsulation layer TFE, first, second, and third color filter layers CF1, CF2, and CF3, a lens layer, an adhesive layer ADL, and an encapsulation substrate ES. The transistor substrate TA may include a substrate SUB and a circuit layer CRL.

Here, the first light-emitting element LED1 may include a first pixel electrode PE1, a light-emitting layer EL, and a common electrode CE, the second light-emitting element LED2 may include a second pixel electrode PE2, the light-emitting layer EL, and the common electrode CE, and the third light-emitting element LED3 may include a third pixel electrode PE3, the light-emitting layer EL, and the common electrode CE.

For example, the transistor substrate TA may include the first and second pixel driving circuit parts PC1 and PC2 of FIG. 3. That is, the transistor substrate TA may include the first, second, third, fourth, and fifth transistors T1, T2, T3, T4, T5 and the capacitor CAP of FIG. 3.

The substrate SUB may include a first pixel circuit area PCAa, a second pixel circuit area PCAb, and a third pixel circuit area PCAc.

In one or more embodiments, the substrate SUB may include a silicon wafer substrate formed by a semiconductor process. The substrate SUB may serve as a supporting member for supporting other components of the display device 100. For example, the substrate SUB may include a semiconductor material (e.g., Group IV semiconductor, Group III-V compound semiconductor, Group II-VI semiconductor, and/or the like). However, the present disclosure is not necessarily limited thereto. In this specification, the substrate SUB may be referred to as a silicon wafer substrate.

The circuit layer CRL may be disposed on the substrate SUB. The circuit layer CRL may include metal layers, insulating layers, gate lines, data lines, emission control lines, and/or the like for driving the first, second, and third light-emitting elements LED1, LED2, and LED3.

The circuit insulating layer PC_IL may be disposed on the circuit layer CRL. The circuit insulating layer PC_IL may prevent contact between the first, second, and third pixel electrodes PE1, PE2, and PE3 and the circuit layer CRL. The circuit insulating layer PC_IL may include organic and/or inorganic materials. For example, the circuit insulating layer PC_IL may include a plurality of layers formed of various insulating materials.

The first, second, and third pixel electrodes PE1, PE2, and PE3 may be disposed on the circuit insulating layer PC_IL. The first pixel electrode PE1 may overlap the first pixel circuit area PCAa, the second pixel electrode PE2 may overlap the second pixel circuit area PCAb, and the third pixel electrode PE3 may overlap the third pixel circuit area PCAc.

The first pixel electrode PE1 may be electrically connected to a transistor of the transistor substrate TA through a contact hole penetrating the circuit insulating layer PC_IL in the first pixel circuit area PCAa. The second pixel electrode PE2 may be electrically connected to a transistor of the transistor substrate TA through a contact hole penetrating the circuit insulating layer PC_IL in the second pixel circuit area PCAb. In addition, the third pixel electrode PE3 may be electrically connected to a transistor of the transistor substrate TA through a contact hole penetrating the circuit insulating layer PC_IL in the third pixel circuit area PCAc.

The first, second, and third pixel electrodes PE1, PE2, and PE3 may include a metal, an alloy, a metal nitride, a conductive metal oxide, a transparent conductive material, and/or the like. The first, second, and third pixel electrodes PE1, PE2, and PE3 may be formed of the same material and may be formed through the same process. For example, the first, second, and third pixel electrodes PE1, PE2, and PE3 may have a multi-layer structure including ITO/Ag/ITO. However, the present disclosure is not necessarily limited thereto. The first, second, and third pixel electrodes PE1, PE2, and PE3 may be anode electrodes. The first, second, and third pixel electrodes PE1, PE2, and PE3 may be reflective electrodes. However, the present disclosure is not limited thereto.

The partition wall PW may be disposed on the circuit insulating layer PC_IL. A pixel opening exposing at least a portion of each of the first, second, and third pixel electrodes PE1, PE2, and PE3 may be defined in the partition wall PW. The partition wall PW may cover the edges of the first, second, and third pixel electrodes PE1, PE2, and PE3. For example, the partition wall PW may include inorganic materials such as silicon oxide, silicon nitride, silicon oxynitride, and/or the like. These may be used alone or in combination with each other. Alternatively, the partition wall PW may include an organic material. In one or more embodiments, the partition wall PW may have a multi-layer structure, but the present disclosure is not necessarily limited thereto.

The pixel opening of the partition wall PW exposing the first pixel electrode PE1 may define a first light-emitting area EAa of the first light-emitting element LED1, the pixel opening of the partition wall PW exposing the second pixel electrode PE2 may define a second light-emitting area EAb of the second light-emitting element LED2, and the pixel opening of the partition wall PW exposing the third pixel electrode PE3 may define a third light-emitting area EAc of the third light-emitting element LED3. That is, the first pixel circuit area PCAa may include the first light-emitting area EAa, the second pixel circuit area PCAb may include the second light-emitting area EAb, and the third pixel circuit area PCAc may include the third light-emitting area EAc.

The light-emitting layer EL may be disposed on the first, second, and third pixel electrodes PE1, PE2, and PE3 and the partition wall PW. The light-emitting layer EL may be a common layer commonly formed across the first, second, and third pixel circuit areas PCAa, PCAb, and PCAc. That is, the light-emitting layer EL may be continuously extend over the entirety of the first, second, and third pixel circuit areas PCAa, PCAb, and PCAc. For example, the light-emitting layer EL may include a hole injection layer, a hole transport layer, an organic light-emitting layer, an electron injection layer, and an electron transport layer. In one or more embodiments, the organic light-emitting layer may include a light-emitting material, which emits white light. For example, the white light may be light in which blue light, green light, and red light are mixed. Alternatively, the white light may be light in which blue light and yellow light are mixed.

However, the present disclosure is not necessarily limited thereto, and the light-emitting layer EL may include a first light-emitting layer that is patterned to overlap the first light-emitting area EAa and includes a light-emitting material that emits red light, a second light-emitting layer that is patterned to overlap the second light-emitting area EAb and includes a light-emitting material that emits green light, and a third light-emitting layer that is patterned to overlap the third light-emitting area EAc and includes a light-emitting material that emits blue light. In this case, the first, second, and third light-emitting layers may be separated from each other, and the first, second, and third color filter layers CF1, CF2, and CF3 may be omitted.

The common electrode CE may be disposed on the light-emitting layer EL. The common electrode CE may be a common layer commonly formed over the first, second, and third pixel circuit areas PCAa, PCAb, and PCAc. That is, the common electrode CE may continuously extend over the entirety of the first, second, and third pixel circuit areas PCAa, PCAb, and PCAc. For example, the common electrode CE may include a metal, an alloy, a metal nitride, a conductive metal oxide, a transparent conductive material, and/or the like. These may be used alone or in combination. The common electrode CE may be a cathode electrode. The common electrode CE may be a transmissive or semi-transmissive electrode.

Accordingly, in the first light-emitting area EAa, the first pixel electrode PE1, the light-emitting layer EL, and the common electrode CE may form the first light-emitting element LED1, in the second light-emitting area EAb, the second pixel electrode PE2, the light-emitting layer EL, and the common electrode CE may form the second light-emitting element LED2, and in the third light-emitting area EAc, the third pixel electrode PE3, the light-emitting layer EL, and the common electrode CE may form the third light-emitting element LED3. For example, the first, second, and third light-emitting elements LED1, LED2, and LED3 may emit light of the same color (e.g., white light). Alternatively, the first, second, and third light-emitting elements LED1, LED2, and LED3 may emit light of different colors.

The encapsulation layer TFE may be disposed on the common electrode CE. The encapsulation layer TFE may continuously extend over the entirety of the first, second, and third pixel circuit areas PCAa, PCAb, and PCAc. The encapsulation layer TFE may prevent impurities, moisture, and/or the like from penetrating into the first, second, and third light-emitting elements LED1, LED2, and LED3 from the outside.

The encapsulation layer TFE may include at least one inorganic layer and at least one organic layer. For example, the encapsulation layer TFE may include a first inorganic encapsulation layer TFE1, an organic encapsulation layer TFE2 disposed on the first inorganic encapsulation layer TFE1, and a second inorganic encapsulation layer TFE3 disposed on the organic encapsulation layer TFE2. The organic encapsulation layer TFE2 may have a substantially flat upper surface.

For example, the first and third inorganic encapsulation layers TFE1 and TFE3 may include silicon oxide, silicon nitride, silicon oxynitride, and/or the like. These may be used alone or in combination with each other. For example, the organic encapsulation layer TFE2 may include a polymer cured material such as polyacrylate and/or the like.

The first, second, and third color filter layers CF1, CF2, and CF3 may be disposed on the encapsulation layer TFE. The first color filter layer CF1 may overlap the first light-emitting area EAa, the second color filter layer CF2 may overlap the second light-emitting area EAb, and the third color filter layer CF3 may overlap the third light-emitting area EAc. The first, second, and third color filter layers CF1, CF2, and CF3 may selectively transmit only light of specific wavelengths and may absorb light of the remaining wavelengths. For example, the first color filter layer CF1 may transmit light of a first color (e.g., red light), the second color filter layer CF2 may transmit light of a second color (e.g., green light), and the third color filter layer CF3 may transmit light of a third color (e.g., blue light). That is, the first, second, and third color filter layers CF1, CF2, and CF3 may be final structures defining the first, second, and third light-emitting areas EAa, EAb, and EAc, respectively.

The first, second, and third color filter layers CF1, CF2, and CF3 may partially overlap in a plan view. For example, the first color filter layer CF1 may partially overlap the second color filter layer CF2, and the second color filter layer CF2 may partially overlap the third color filter layer CF3. Accordingly, an overlapping portion of the first, second, and third color filter layers CF1, CF2, and CF3 may serve as a light-blocking layer. The light-blocking layer may block incident light and may prevent color mixing between the first, second, and third light-emitting areas EAa, EAb, and EAc. Alternatively, a separate light-blocking layer may be disposed between the first, second, and third color filter layers CF1, CF2, and CF3.In this case, the separate light-blocking layer may be a black matrix.

A lens layer may be disposed on the first, second, and third color filter layers CF1, CF2, and CF3. The lens layer may include a plurality of microlenses ML. The microlenses ML may improve light extraction efficiency. Each of the microlenses ML may overlap the first, second, and third light-emitting areas EAa, EAb, and EAc. The microlenses ML may have a suitable refractive index (e.g., a predetermined refractive index) with respect to visible light. For example, the microlenses ML may have a refractive index of about 1.5 or more to about 1.7 or less with respect to visible light. However, the present disclosure is not necessarily limited thereto. For example, each of the microlenses ML may have a convex cross-sectional shape.

The encapsulation substrate ES may be disposed on the lens layer. The encapsulation substrate ES may be attached to the lens layer through the adhesive layer ADL. The encapsulation substrate ES may protect the display panel 110 from moisture and/or gas penetration. The encapsulation substrate ES may include a transparent insulating substrate. For example, the encapsulation substrate ES may include glass. For example, the adhesive layer ADL may include an optical clear adhesive (OCA), a pressure sensitive adhesive (PSA), a photo-curable resin, a thermosetting resin, and/or the like.

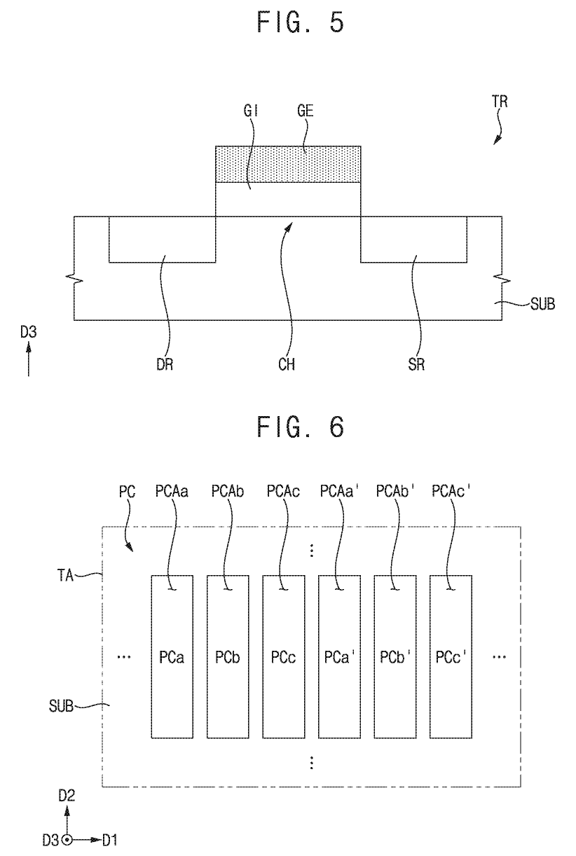

FIG. 5 is a cross-sectional view illustrating one transistor included in a transistor substrate of FIG. 4.

Referring to FIGS. 4 and 5, the transistor substrate TA may include at least one transistor TR formed by a semiconductor process. For example, the transistor TR may correspond to any one of the first, second, third, fourth, and fifth transistors T1, T2, T3, T4, and T5 of FIG. 3.

The transistor TR may include an active portion, a gate insulating layer GI, and a gate electrode GE. A portion of the substrate SUB may define the active portion. That is, the substrate SUB may include the active portion. The active portion may include a source region SR, a drain region DR, and a channel region CH.

The substrate SUB may include a semiconductor material. In one or more embodiments, the substrate SUB may be an n-type semiconductor substrate doped with n-type impurities or a p-type semiconductor substrate doped with p-type impurities.

The source region SR and the drain region DR may be disposed inside the active portion. Specifically, the source region SR may be disposed at one side of the inside of the active portion, and the drain region DR may be disposed at the other side of the inside of the active portion. For example, the source region SR and the drain region DR may include the same semiconductor material as the substrate SUB. The source region SR and the drain region DR may be a source electrode and a drain electrode of the transistor TR, respectively.

The source region SR and the drain region DR may be doped with impurities. Accordingly, the source region SR and the drain region DR may be conductive regions. The doping concentration of each of the source region SR and the drain region DR may be higher than the doping concentration of the substrate SUB. In one or more embodiments, the source region SR and the drain region DR may be doped with p-type impurities. However, the present disclosure is not necessarily limited thereto.

At least a portion of the substrate SUB contacting the source region SR and the drain region DR may be doped with impurities of a type opposite to the source region SR and the drain region DR. For example, a well region doped with impurities of a type opposite to the source region SR and the drain region DR and contacting the source region SR and the drain region DR may be formed inside the substrate SUB. In this case, the substrate SUB may be a semiconductor substrate doped with the same type of impurities as the source region SR and the drain region DR.

In one or more embodiments, in a case that the source region SR and the drain region DR are doped with p-type impurities, at least a portion of the substrate SUB contacting the source region SR and the drain region DR (i.e., a well region) may be doped with n-type impurities.

The channel region CH may be located between the source region SR and the drain region DR inside the substrate SUB. For example, the channel region CH may include the same semiconductor material as the substrate SUB. The channel region CH may be a region of the substrate SUB in which carriers having electric charge conduct in case that a voltage is applied to the gate electrode GE.

The channel region CH may be defined as a current path formed between the source region SR and the drain region DR. For example, in a case that the source region SR and the drain region DR are doped with p-type impurities, the channel region CH may be formed in case that a negative voltage is applied to the gate electrode GE, and current may be transmitted through the movement of holes.

The gate insulating layer GI may be disposed on the substrate SUB. Specifically, the gate insulating layer GI may overlap the channel region CH. The gate insulating layer GI may include silicon oxide (e.g., SiO₂), silicon nitride, or an insulating material having a high dielectric constant. The insulating material having a high dielectric constant may refer to a dielectric material having a dielectric constant higher than a dielectric constant of the silicon oxide. For example, the insulating material having a high dielectric constant may include aluminum oxide (Al₂O₃), tantalum oxide (Ta₂O₅), titanium oxide (TiO₂), yttrium oxide (Y₂O₃), zirconium oxide (ZrO₂), zirconium silicon oxide (ZrSixO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃), and/or the like. These may be used alone or in combination with each other. However, the present disclosure is not necessarily limited thereto.

The gate electrode GE may be disposed on the gate insulating layer GI. The gate electrode GE may overlap the channel region CH in a plan view. The gate electrode GE may include a metal, a metal nitride, and/or the like. Examples of the metal may include aluminum, tungsten, copper, molybdenum, and/or the like. Examples of the metal nitride may include titanium nitride (TiN), tantalum nitride (TaN), tungsten nitride (WN), and/or the like. These may be used alone or in combination with each other. Alternatively, the gate electrode GE may include a semiconductor material such as doped polysilicon and/or the like. In addition, the gate electrode GE may have a single-layer structure or a multi-layer structure including a plurality of layers.

FIG. 6 is a plan view illustrating a transistor substrate of FIG. 4.

Referring to FIGS. 4 and 6, as described above, the transistor substrate TA may include the substrate SUB and the circuit layer CRL. The substrate SUB may further include a fourth pixel circuit area PCAa′, a fifth pixel circuit area PCAb′, and a sixth pixel circuit area PCAc′.

For example, the second pixel circuit area PCAb may be located in the first direction D1 from the first pixel circuit area PCAa, and the third pixel circuit area PCAc may be located in the first direction D1 from the second pixel circuit area PCAb. In addition, the fourth pixel circuit area PCAa′ may be located in the first direction D1 from the third pixel circuit area PCAc, the fifth pixel circuit area PCAb′ may be located in the first direction D1 from the fourth pixel circuit area PCAa′, and the sixth pixel circuit area PCAc′ may be located in the first direction D1 from the fifth pixel circuit area PCAb′. That is, the first pixel circuit area PCAa, the second pixel circuit area PCAb, the third pixel circuit area PCAc, the fourth pixel circuit area PCAa′, the fifth pixel circuit area PCAb′, and the sixth pixel circuit area PCAc′ may be sequentially disposed along the first direction D1.

In the first, second, third, fourth, fifth, and sixth pixel circuit areas PCAa, PCAb, PCAc, PCAa′, PCAb′, and PCAc′, a plurality of pixel driving circuit parts PC included in the circuit layer CRL may be disposed.

The pixel driving circuit parts PC may include a first pixel driving circuit part PCa, a second pixel driving circuit part PCb, a third pixel driving circuit part PCc, a fourth pixel driving circuit part PCa′, a fifth pixel driving circuit part PCb′, and a sixth pixel driving circuit part PCc′. Here, among the first pixel driving circuit part PCa, the second pixel driving circuit part PCb, the third pixel driving circuit part PCc, the fourth pixel driving circuit part PCa′, the fifth pixel driving circuit part PCb′, and the sixth pixel driving circuit part PCc′, two adjacent pixel driving circuit parts may correspond to the first pixel driving circuit part PC1 and the second pixel driving circuit part PC2 of FIG. 3.

The first pixel driving circuit part PCa may be disposed in the first pixel circuit area PCAa and may be electrically connected to the first light-emitting element LED1 defining the first light-emitting area EAa. The second pixel driving circuit part PCb may be disposed in the second pixel circuit area PCAb and may be electrically connected to the second light-emitting element LED2 defining the second light-emitting area EAb. The third pixel driving circuit part PCc may be disposed in the third pixel circuit area PCAc and may be electrically connected to the third light-emitting element LED3 defining the third light-emitting area EAc.

In addition, the fourth pixel driving circuit part PCa′ may be disposed in the fourth pixel circuit area PCAa′ and may be electrically connected to a fourth light-emitting element defining a fourth light-emitting area. The fifth pixel driving circuit part PCb′ may be disposed in the fifth pixel circuit area PCAb′ and may be electrically connected to a fifth light-emitting element defining a fifth light-emitting area. The sixth pixel driving circuit part PCc′ may be disposed in the sixth pixel circuit area PCAc′ and may be electrically connected to a sixth light-emitting element defining a sixth light-emitting area.

The first, second, and third light-emitting areas EAa, EAb, and EAc may emit light of different colors from each another, and the fourth, fifth, and sixth light-emitting areas may emit light of different colors from each another. For example, the first light-emitting area EAa and the fourth light-emitting area may emit light of a first color (e.g., red light), the second light-emitting area EAb and the fifth light-emitting area may emit light of a second color (e.g., green light), and the third light-emitting area EAc and the sixth light-emitting area may emit light of a third color (e.g., blue light). However, the present disclosure is not necessarily limited thereto. In this specification, the color of the light emitted from the light-emitting area denotes a final color expressed through the display device 100.

In one or more embodiments, the first, second, and third light-emitting elements LED1, LED2, and LED3 may emit light of the same color, and the fourth, fifth, and sixth light-emitting elements may emit light of the same color. For example, the first, second, and third light-emitting elements LED1, LED2, and LED3 may emit white light, and the fourth, fifth, and sixth light-emitting elements may emit white light. In this case, color filter layers (e.g., CF1, CF2, and CF3 of FIG. 4) may be disposed on the first, second, and third light-emitting elements LED1, LED2, and LED3 and the fourth, fifth, and sixth light-emitting elements. However, the present disclosure is not necessarily limited thereto.

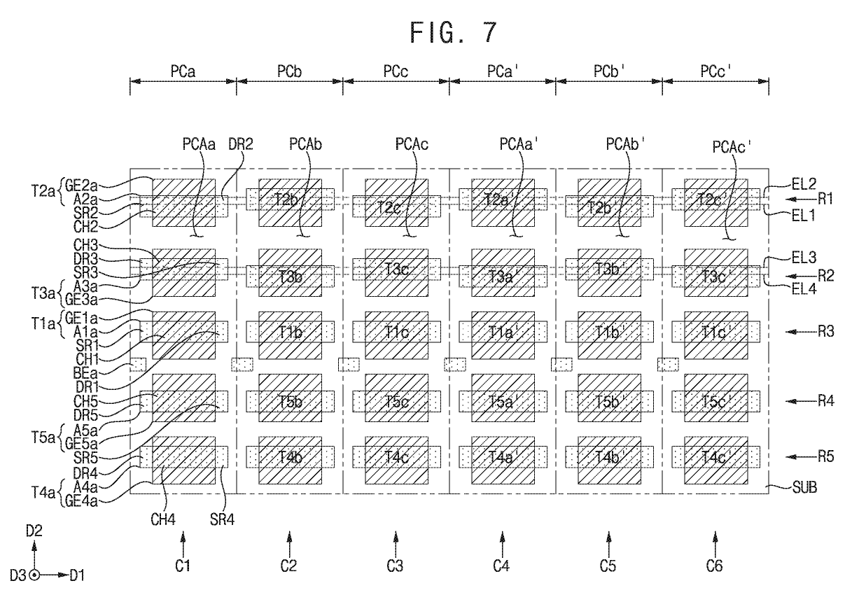

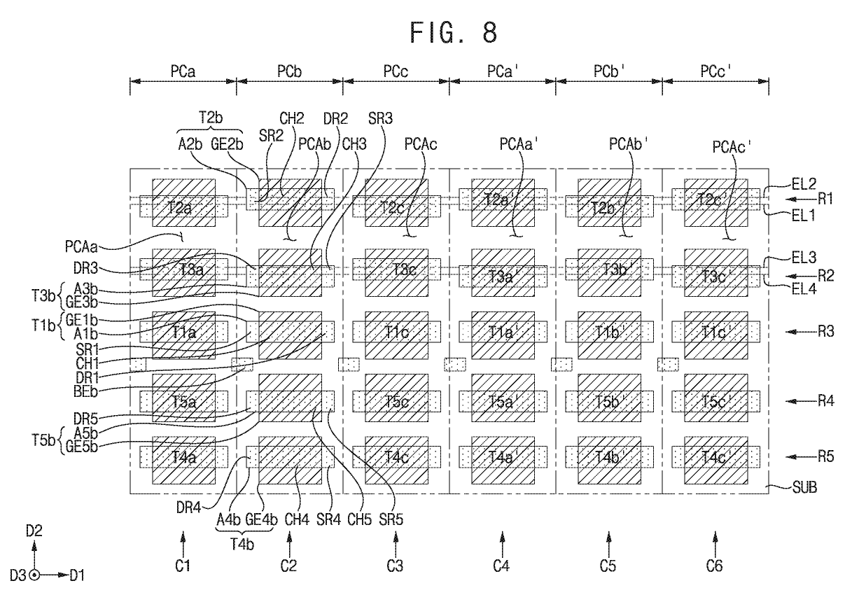

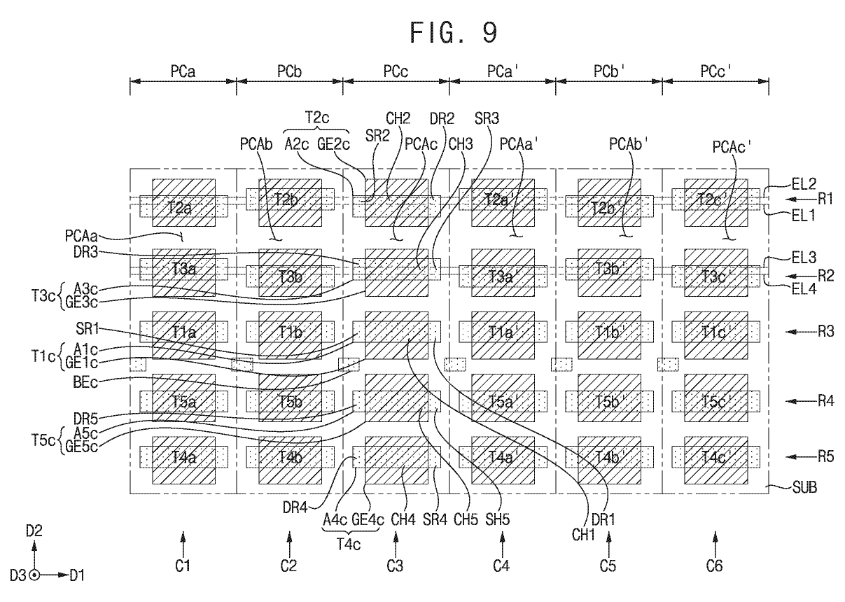

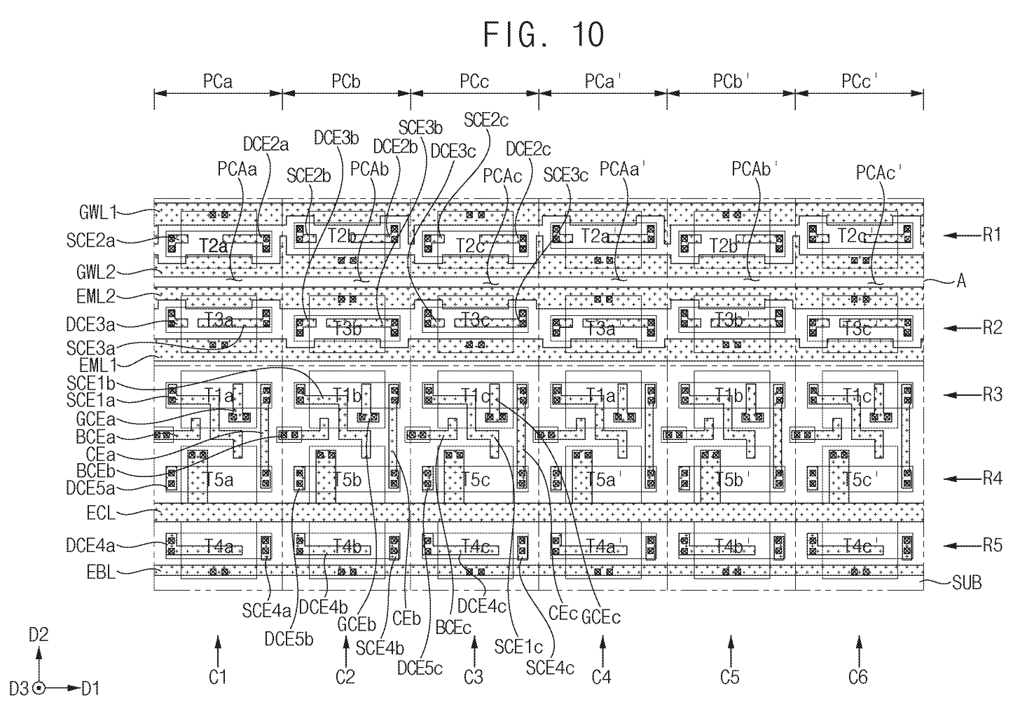

FIGS. 7, 8 and 9, are layout views illustrating an example of first, second, third, fourth, fifth, and sixth pixel driving circuit parts included in the transistor substrate of FIG. 6. Here, FIGS. 7, 8 and 9, are the same layout views. However, in order to secure display spaces for reference numerals, FIG. 7 includes reference numerals related to the first pixel driving circuit part PCa, FIG. 8 includes reference numerals related to the second pixel driving circuit part PCb, and FIG. 9 includes reference numerals related to the third pixel driving circuit part PCc.

Hereinafter, an example of an arrangement structure of transistors included in the first, second, and third pixel driving circuit parts PCa, PCb, and PCc of the transistor substrate TA will be described in more detail. In addition, the following description of the first, second, and third pixel driving circuit parts PCa, PCb, and PCc may be substantially equally applied to the fourth, fifth, and sixth pixel driving circuit parts PCa', PCb', and PCc'.

Referring to FIGS. 7, 8 and 9, the first pixel driving circuit part PCa may include a first driving transistor T1a, a first data writing transistor T2a, a first operation control transistor T3a, a first initialization transistor T4a, and a first emission control transistor T5a disposed in the first pixel circuit area PCAa. The second pixel driving circuit part PCb may include a second driving transistor T1b, a second data writing transistor T2b, a second operation control transistor T3b, a second initialization transistor T4b, and a second emission control transistor T5b disposed in the second pixel circuit area PCAb. In addition, the third pixel driving circuit part PCc may include a third driving transistor T1c, a third data writing transistor T2c, a third operation control transistor T3c, a third initialization transistor T4c, and a third light-emission control transistor T5c disposed in the third pixel circuit area PCAc.

Likewise, the fourth pixel driving circuit part PCa' may include a fourth driving transistor T1a', a fourth data writing transistor T2a', a fourth operation control transistor T3a', a fourth initialization transistor T4a', and a fourth emission control transistor T5a' disposed in the fourth pixel circuit area PCAa'. The fifth pixel driving circuit part PCb' may include a fifth driving transistor T1b', a fifth data writing transistor T2b', a fifth operation control transistor T3b', a fifth initialization transistor T4b', and a fifth emission control transistor T5b' disposed in the fifth pixel circuit area PCAb'. In addition, the sixth pixel driving circuit part PCc' may include a sixth driving transistor T1c', a sixth data writing transistor T2c', a sixth operation control transistor T3c', a sixth initialization transistor T4c', and a sixth emission control transistor T5c' disposed in the sixth pixel circuit area PCAc'.

Here, the first, second, third, fourth, fifth, and sixth driving transistors T1a, T1b, T1c, T1a', T1b', and T1c' may correspond to the first transistor T1 of FIG. 3, the first, second, third, fourth, fifth, and sixth data writing transistors T2a, T2b, T2c, T2a', T2b', and T2c' may correspond to the second transistor T2 of FIG. 3, the first, second, third, fourth, fifth, and sixth operation control transistors T3a, T3b, T3c, T3a', T3b', and T3c' may correspond to the third transistor T3 of FIG. 3, the first, second, third, fourth, fifth, and sixth initialization transistors T4a, T4b, T4c, T4a', T4b', and T4c' may correspond to the fourth transistor T4 of FIG. 3, and the first, second, third, fourth, fifth, and sixth emission control transistors T5a, T5b, T5c, T5a', T5b', and T5c' may correspond to the fifth transistor T5 of FIG. 3.

That is, the first, second, third, fourth, fifth, and sixth driving transistors T1a, T1b, T1c, T1a', T1b', and T1c' may generate a driving current, the first, second, third, fourth, fifth, and sixth data writing transistors T2a, T2b, T2c, T2a', T2b', and T2c' may receive a data voltage (e.g., VDATA1 or VDATA2 of FIG. 3) or a reference voltage (e.g., VREF1 or VREF2 of FIG. 3) in response to a gate writing signal (e.g., GW1 or GW2 of FIG. 3), the first, second, third, fourth, fifth, and sixth operation control transistors T3a, T3b, T3c, T3a', T3b', and T3c' may receive a driving voltage (e.g., ELVDD of FIG. 3) in response to an emission control signal (e.g., EM1 or EM2 of FIG. 3), the first, second, third, fourth, fifth, and sixth initialization transistors T4a, T4b, T4c, T4a', T4b', and T4c' may receive an initialization voltage (e.g., VINT of FIG. 3) in response to an initialization gate signal (e.g., EB of FIG. 3), and the first, second, third, fourth, fifth, and sixth emission control transistors T5a, T5b, T5c, T5a', T5b', and T5c' may supply the driving current to the light-emitting element in response to the emission control signal (e.g., EC of FIG. 3).

The first, second, third, fourth, fifth, and sixth pixel circuit areas PCAa, PCAb, PCAc, PCAa’, PCAb’, and PCAc’ may be disposed in a plurality of columns extending in the second direction D2. Specifically, the first pixel circuit area PCAa may be disposed in a first column C1, the second pixel circuit area PCAb may be disposed in a second column C2 adjacent to the first column C1 in the first direction D1, and the third pixel circuit area PCAc may be disposed in a third column C3 adjacent to the second column C2 in the first direction D1. In addition, the fourth pixel circuit area PCAa' may be disposed in a fourth column C4 adjacent to the third column C3 in the first direction D1, the fifth pixel circuit area PCAb' may be disposed in a fifth column C5 adjacent to the fourth column C4 in the first direction D1, and the sixth pixel circuit area PCAc' may be disposed in a sixth column C6 adjacent to the fifth column C5 in the first direction D1.

The first driving transistor T1a, the first data writing transistor T2a, the first operation control transistor T3a, the first initialization transistor T4a, and the first emission control transistor T5a may be disposed in a line along the second direction D2. In one or more embodiments, the first data writing transistor T2a, the first operation control transistor T3a, the first driving transistor T1a, the first emission control transistor T5a, and the first initialization transistor T4a may be sequentially disposed along a direction opposite to the second direction D2. However, the present disclosure is not necessarily limited thereto, and the positions of the transistors disposed in the first pixel circuit area PCAa may be changed from each other.

The second driving transistor T1b, the second data writing transistor T2b, the second operation control transistor T3b, the second initialization transistor T4b, and the second emission control transistor T5b may be disposed in a line along the second direction D2. In embodiments, the second data writing transistor T2b, the second operation control transistor T3b, the second driving transistor T1b, the second emission control transistor T5b, and the second initialization transistor T4b may be sequentially disposed in the direction opposite to the second direction D2. However, the present disclosure is not necessarily limited thereto, and the positions of the transistors disposed in the second pixel circuit area PCAb may be changed.

The third driving transistor T1c, the third data writing transistor T2c, the third operation control transistor T3c, the third initialization transistor T4c, and the third emission control transistor T5c may be disposed in a line along the second direction D2. In one or more embodiments, the third data writing transistor T2c, the third operation control transistor T3c, the third driving transistor T1c, the third emission control transistor T5c, and the third initialization transistor T4c may be sequentially disposed in the direction opposite to the second direction D2. However, the present disclosure is not necessarily limited thereto, and the positions of the transistors disposed in the third pixel circuit area PCAc may be changed.

The arrangement order of the transistors disposed in the fourth pixel circuit area PCAa′ may be the same as the arrangement order of the transistors disposed in the first pixel circuit area PCAa, the arrangement order of the transistors disposed in the fifth pixel circuit area PCAb′ may be the same as the arrangement order of the transistors disposed in the second pixel circuit area PCAb, and the arrangement order of the transistors disposed in the sixth pixel circuit area PCAc′ may be the same as the arrangement order of the transistors disposed in the third pixel circuit area PCAc.

The first, second, third, fourth, fifth, and sixth data writing transistors T2a, T2b, T2c, T2a′, T2b′, and T2c′, the first, second, third, fourth, fifth, and sixth operation control transistors T3a, T3b, T3c, T3a′, T3b′, and T3c′, the first, second, third, fourth, fifth, and sixth driving transistors T1a, T1b, T1c, T1a′, T1b′, and T1c′, the first, second, third, fourth, fifth, and sixth emission control transistors T5a, T5b, T5c, T5a′, T5b′, and T5c′, and the first, second, third, fourth, fifth, and sixth initialization transistors T4a, T4b, T4c, T4a′, T4b′, and T4c′ may be disposed in a plurality of rows extending in the first direction D1. Specifically, the first, second, third, fourth, fifth, and sixth data writing transistors T2a, T2b, T2c, T2a′, T2b′, and T2c′ may be sequentially disposed along the first direction D1 in a first row R1, the first, second, third, fourth, fifth, and sixth operation control transistors T3a, T3b, T3c, T3a′, T3b′, and T3c′ may be sequentially disposed along the first direction D1 in a second row R2 adjacent to the first row R1 in the direction opposite to the second direction D2, and the first, second, third, fourth, fifth, and sixth driving transistors T1a, T1b, T1c, T1a′, T1b′, and T1c′ may be sequentially disposed along the first direction D1 in a third row R3 adjacent to the second row R2 in the direction opposite to the second direction D2. In addition, the first, second, third, fourth, fifth, and sixth emission control transistors T5a, T5b, T5c, T5a′, T5b′, and T5c′ may be sequentially disposed along the first direction D1 in a fourth row R4 adjacent to the third row R3 in the direction opposite to the second direction D2, and the first, second, third, fourth, fifth, and sixth initialization transistors T4a, T4b, T4c, T4a′, T4b′, and T4c′ may be sequentially disposed along the first direction D1 in a fifth row R5 adjacent to the fourth row R4 in the direction opposite to the second direction D2.

As illustrated in FIG. 7, the first driving transistor T1a may include a first active portion A1a and a first gate electrode GE1a disposed on the first active portion A1a. The first data writing transistor T2a may include a second active portion A2a and a second gate electrode GE2a disposed on the second active portion A2a. The first operation control transistor T3a may include a third active portion A3a and a third gate electrode GE3a disposed on the third active portion A3a. The first initialization transistor T4a may include a fourth active portion A4a and a fourth gate electrode GE4a disposed on the fourth active portion A4a. The first emission control transistor T5a may include a fifth active portion A5a and a fifth gate electrode GE5a disposed on the fifth active portion A5a. The first, second, third, fourth, and fifth active portions A1a, A2a, A3a, A4a, and A5a may be included in the substrate SUB.

The first active portion A1a may include a first source region SR1, a first drain region DR1, and a first channel region CH1 between the first source region SR1 and the first drain region DR1. The second active portion A2a may include a second source region SR2, a second drain region DR2, and a second channel region CH2 between the second source region SR2 and the second drain region DR2. The third active portion A3a may include a third source region SR3, a third drain region DR3, and a third channel region CH3 between the third source region SR3 and the third drain region DR3. The fourth active portion A4a may include a fourth source region SR4, a fourth drain region DR4, and a fourth channel region CH4 between the fourth source region SR4 and the fourth drain region DR4. In addition, the fifth active portion A5a may include a fifth source region SR5, a fifth drain region DR5, and a fifth channel region CH5 between the fifth source region SR5 and the fifth drain region DR5. The first, second, third, fourth, and fifth source regions SR1, SR2, SR3, SR4, and SR5 may be source electrodes of the corresponding transistors T1a, T2a, T3a, T4a, and T5a, and the first, second, third, fourth, and fifth drain regions DR1, DR2, DR3, DR4, and DR5 may be drain electrodes of the corresponding transistors T1a, T2a, T3a, T4a, and T5a.

The substrate SUB may further include a first body electrode BEa of the transistors T1a, T2a, T3a, T4a, and T5a. The first body electrode BEa may be disposed between the first source region SR1 of the first driving transistor T1a and the fifth drain region DR5 of the first emission control transistor T5a. The first body electrode BEa may receive the driving voltage (e.g., the driving voltage ELVDD of FIG. 3).

The first gate electrode GE1a may overlap the first channel region CH1 of the first active portion A1a in a plan view, the second gate electrode GE2a may overlap the second channel region CH2 of the second active portion A2a in a plan view, the third gate electrode GE3a may overlap the third channel region CH3 of the third active portion A3a in a plan view, the fourth gate electrode GE4a may overlap the fourth channel region CH4 of the fourth active portion A4a in a plan view, and the fifth gate electrode GE5a may overlap the fifth channel region CH5 of the fifth active portion A5a in a plan view.

As illustrated in FIG. 8, the second driving transistor T1b may include a first active portion A1b and a first gate electrode GE1b disposed on the first active portion A1b. The second data writing transistor T2b may include a second active portion A2b and a second gate electrode GE2b disposed on the second active portion A2b. The second operation control transistor T3b may include a third active portion A3b and a third gate electrode GE3b disposed on the third active portion A3b. The second initialization transistor T4b may include a fourth active portion A4b and a fourth gate electrode GE4b disposed on the fourth active portion A4b. The second emission control transistor T5b may include a fifth active portion A5b and a fifth gate electrode GE5b disposed on the fifth active portion A5b. The first, second, third, fourth, and fifth active portions A1b, A2b, A3b, A4b, and A5b may be included in the substrate SUB.

The first active portion A1b may include a first source region SR1, a first drain region DR1, and a first channel region CH1 between the first source region SR1 and the first drain region DR1. The second active portion A2b may include a second source region SR2, a second drain region DR2, and a second channel region CH2 between the second source region SR2 and the second drain region DR2. The third active portion A3b may include a third source region SR3, a third drain region DR3, and a third channel region CH3 between the third source region SR3 and the third drain region DR3. The fourth active portion A4b may include a fourth source region SR4, a fourth drain region DR4, and a fourth channel region CH4 between the fourth source region SR4 and the fourth drain region DR4. In addition, the fifth active portion A5b may include a fifth source region SR5, a fifth drain region DR5, and a fifth channel region CH5 between the fifth source region SR5 and the fifth drain region DR5. The first, second, third, fourth, and fifth source regions SR1, SR2, SR3, SR4, and SR5 may be source electrodes of the corresponding transistors T1b, T2b, T3b, T4b, and T5b, and the first, second, third, fourth, and fifth drain regions DR1, DR2, DR3, DR4, and DR5 may be drain electrodes of the corresponding transistors T1b, T2b, T3b, T4b, and T5b.

The substrate SUB may further include a second body electrode BEb of the transistors T1b, T2b, T3b, T4b, and T5b. The second body electrode BEb may be disposed between the first source region SR1 of the second driving transistor T1b and the fifth drain region DR5 of the second emission control transistor T5b. The second body electrode BEb may receive the driving voltage (e.g., the driving voltage ELVDD of FIG. 3).

The first gate electrode GE1b may overlap the first channel region CH1 of the first active portion A1b in a plan view, the second gate electrode GE2b may overlap the second channel region CH2 of the second active portion A2b in a plan view, the third gate electrode GE3b may overlap the third channel region CH3 of the third active portion A3b in a plan view, the fourth gate electrode GE4b may overlap the fourth channel region CH4 of the fourth active portion A4b in a plan view, and the fifth gate electrode GE5b may overlap the fifth channel region CH5 of the fifth active portion A5b in a plan view.

As illustrated in FIG. 9, the third driving transistor T1c may include the first active portion A1c and the first gate electrode GE1c disposed on the first active portion A1c, the third data writing transistor T2c may include the second active portion A2c and the second gate electrode GE2c disposed on the second active portion A2c, the third operation control transistor T3c may include the third active portion A3c and the third gate electrode GE3c disposed on the third active portion A3c, the third initialization transistor T4c may include the fourth active portion A4c and the fourth gate electrode GE4c disposed on the fourth active portion A4c, and the third emission control transistor T5c may include the fifth active portion A5c and the fifth gate electrode GE5c disposed on the fifth active portion A5c. The first, second, third, fourth, and fifth active portions A1c, A2c, A3c, A4c, and A5c may be included in the substrate SUB.

The first active portion A1c may include the first source region SR1, the first drain region DR1, and the first channel region CH1 between the first source region SR1 and the first drain region DR1. The second active portion A2c may include the second source region SR2, the second drain region DR2, and the second channel region CH2 between the second source region SR2 and the second drain region DR2. The third active portion A3c may include the third source region SR3, the third drain region DR3, and the third channel region CH3 between the third source region SR3 and the third drain region DR3. The fourth active portion A4c may include the fourth source region SR4, the fourth drain region DR4, and the fourth channel region CH4 between the fourth source region SR4 and the fourth drain region DR4. In addition, the fifth active portion A5c may include the fifth source region SR5, the fifth drain region DR5, and the fifth channel region CH5 between the fifth source region SR5 and the fifth drain region DR5. The first, second, third, fourth, and fifth source regions SR1, SR2, SR3, SR4, and SR5 may be source electrodes of the corresponding transistors T1c, T2c, T3c, T4c, and T5c, and the first, second, third, fourth, and fifth drain regions DR1, DR2, DR3, DR4, and DR5 may be drain electrodes of the corresponding transistors T1c, T2c, T3c, T4c, and T5c.

The substrate SUB may further include a third body electrode BEc of the transistors T1c, T2c, T3c, T4c, and T5c. The third body electrode BEc may be disposed between the first source region SR1 of the third driving transistor T1c and the fifth drain region DR5 of the third emission control transistor T5c. The third body electrode BEc may receive the driving voltage (e.g., the driving voltage ELVDD of FIG. 3).

The first gate electrode GE1c may overlap the first channel region CH1 of the first active portion A1c in a plan view, the second gate electrode GE2c may overlap the second channel region CH2 of the second active portion A2c in a plan view, the third gate electrode GE3c may overlap the third channel region CH3 of the third active portion A3c in a plan view, the fourth gate electrode GE4c may overlap the fourth channel region CH4 of the fourth active portion A4c in a plan view, and the fifth gate electrode GE5c may overlap the fifth channel region CH5 of the fifth active portion A5c in a plan view.

For example, the first, second, third, fourth, and fifth source regions SR1, SR2, SR3, SR4, and SR5 and the first, second, third, fourth, and fifth drain regions DR1, DR2, DR3, DR4, and DR5 may be doped with impurities (e.g., p-type impurities).

In one or more embodiments, an element isolation film including an insulating material may be formed between the first, second, third, fourth, and fifth active portions A1a, A1b, A1c, A2a, A2b, A2c, A3a, A3b, A3c, A4a, A4b, A4c, A5a, A5b, and A5c.

The first, second, third, fourth, and fifth gate electrodes GE1a, GE1b, GE1c, GE2a, GE2b, GE2c, GE3a, GE3b, GE3c, GE4a, GE4b, GE4c, GE5a, GE5b, and GE5c may include the same material and may be disposed in (e.g., at) the same layer.

A gate insulating layer may be disposed between the first, second, third, fourth, and fifth gate electrodes GE1a, GE1b, GE1c, GE2a, GE2b, GE2c, GE3a, GE3b, GE3c, GE4a, GE4b, GE4c, GE5a, GE5b, and GE5c and the corresponding first, second, third, fourth, and fifth channel regions CH1, CH2, CH3, CH4, and CH5. For example, the gate insulating layer may include silicon oxide (e.g., SiO₂), silicon nitride, or an insulating material having a high dielectric constant.

Likewise, each transistor T1a', T1b', T1c', T2a', T2b', T2c', T3a', T3b', T3c', T4a', T4b', T4c', T5a', T5b', and T5c' included in the fourth, fifth, and sixth pixel driving circuit parts PCa', PCb', and PCc' may include an active portion including a source region, a drain region, and a channel region, and a gate electrode disposed on the active portion.

In one or more embodiments, the centers (i.e., centers of the channel regions) of the first, third, and fifth data writing transistors T2a, T2c, and T2b' disposed in the first pixel circuit area PCAa, the third pixel circuit area PCAc, and the fifth pixel circuit area PCAb', respectively, may coincide with a virtual first line EL1 extending in the first direction D1. The centers (i.e., centers of the channel regions) of the second, fourth, and sixth data writing transistors T2b, T2a', and T2c' disposed in the second pixel circuit area PCAb, the fourth pixel circuit area PCAa', and the sixth pixel circuit area PCAc', respectively, may coincide with a virtual second line EL2 extending in the first direction D1. In this case, the virtual first line EL1 and the virtual second line EL2 may not overlap and may be parallel to each other. However, the present disclosure is not necessarily limited thereto. In another embodiment, the centers (i.e., centers of the channel regions) of the first, second, third, fourth, fifth, and sixth data writing transistors T2a, T2b, T2c, T2a', T2b', and T2c' disposed in the first, second, third, fourth, fifth, and sixth pixel circuit areas PCAa, PCAb, PCAc, PCAa', PCAb', and PCAc' may coincide with the same virtual line extending in the first direction D1.

In one or more embodiments, the centers (i.e., centers of the channel regions) of the first, third, and fifth operation control transistors T3a, T3c, and T3b' disposed in the first pixel circuit area PCAa, the third pixel circuit area PCAc, and the fifth pixel circuit area PCAb', respectively, may coincide with a virtual third line EL3 extending in the first direction D1. The centers (i.e., centers of the channel regions) of the second, fourth, and sixth operation control transistors T3b, T3a', and T3c' disposed in the second pixel circuit area PCAb, the fourth pixel circuit area PCAa', and the sixth pixel circuit area PCAc', respectively, may coincide with a virtual fourth line EL4 extending in the first direction D1. In this case, the virtual third line EL3 and the virtual fourth line EL4 may not overlap and may be parallel to each other. However, the present disclosure is not necessarily limited thereto. In another embodiment, the centers (i.e., centers of the channel regions) of the first, second, third, fourth, fifth, and sixth operation control transistors T3a, T3b, T3c, T3a', T3b', and T3c' disposed in the first, second, third, fourth, fifth, and sixth pixel circuit areas PCAa, PCAb, PCAc, PCAa', PCAb', and PCAc' may coincide with the same virtual line extending in the first direction D1.

The components illustrated in FIGS. 7, 8 and 9, may be repeatedly arranged along the first direction D1 and the second direction D2.

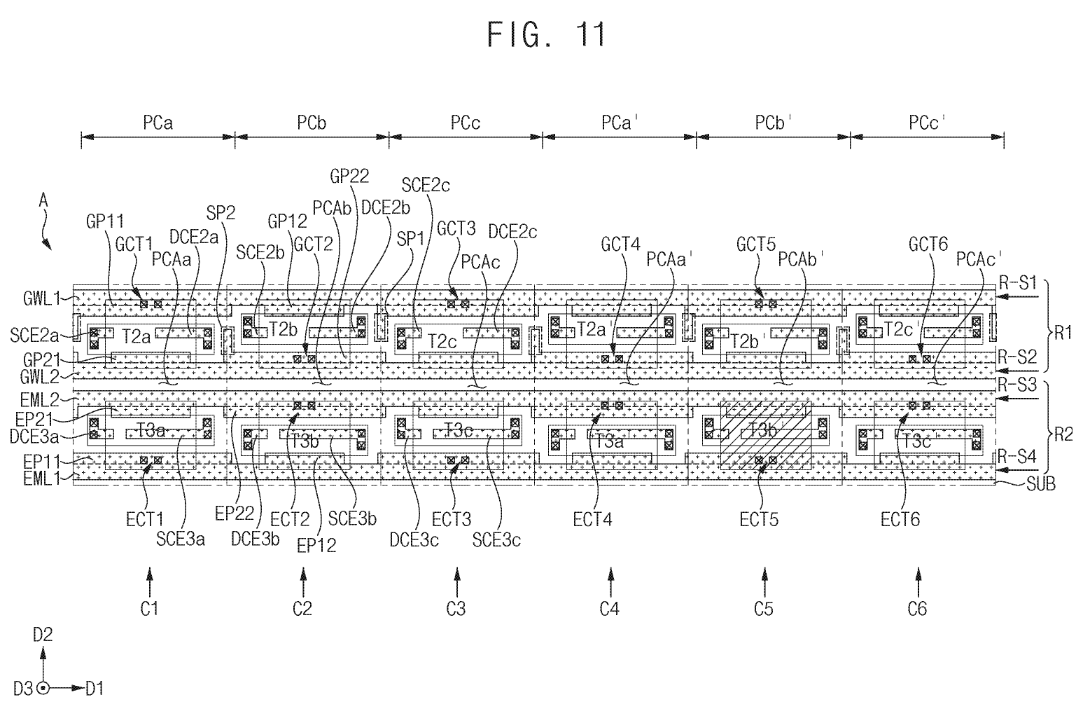

FIG. 10 is a layout view illustrating a metal layer disposed on the first, second, third, fourth, fifth, and sixth pixel driving circuit parts of FIG. 9. FIG. 11 is an enlarged layout view of an area A of FIG. 10.

Hereinafter, components of the metal layer disposed in the first, second, and third pixel circuit areas PCAa, PCAb, and PCAc of the transistor substrate TA will be described in more detail. In addition, the following description of the components of the metal layer disposed in the first, second, and third pixel circuit areas PCAa, PCAb, and PCAc may be substantially equally applied to the components of the metal layer disposed in the fourth, fifth, and sixth pixel circuit areas PCAa', PCAb', and PCAc'.

Referring further to FIG. 10, a circuit insulating layer may be disposed on the first, second, third, fourth, fifth, and sixth pixel driving circuit parts PCa, PCb, PCc, PCa', PCb', and PCc'. For example, the circuit insulating layer may include an organic insulating material.

The metal layer may be disposed on the circuit insulating layer. The metal layer may include first source connection electrodes SCE1a, SCE1b, and SCE1c, second source connection electrodes SCE2a, SCE2b, and SCE2c, third source connection electrodes SCE3a, SCE3b, and SCE3c, fourth source connection electrodes SCE4a, SCE4b, and SCE4c, second drain connection electrodes DCE2a, DCE2b, and DCE2c, third drain connection electrodes DCE3a, DCE3b, and DCE3c, fourth drain connection electrodes DCE4a, DCE4b, and DCE4c, fifth drain connection electrodes DCE5a, DCE5b, and DCE5c, first, second, and third gate connection electrodes GCEa, GCEb, and GCEc, first, second, and third connection electrodes CEa, CEb, and CEc, first, second, and third body connection electrodes BCEa, BCEb, and BCEc, the first write gate line GWL1, the second write gate line GWL2, the first emission control line EML1, the second emission control line EML2, the emission control line ECL, and the initialization gate line EBL. That is, the components of the metal layer may include the same material and may be disposed in (e.g., at) the same layer.

The first source connection electrode SCE1a may be disposed in each of the first pixel circuit area PCAa and the fourth pixel circuit area PCAa' and may be connected to the first source region SR1 of the first driving transistor T1a through a contact hole penetrating the circuit insulating layer. The first gate connection electrode GCEa may be disposed in each of the first pixel circuit area PCAa and the fourth pixel circuit area PCAa' and may be connected to the first gate electrode GE1a of the first driving transistor T1a through a contact hole penetrating the circuit insulating layer. The first connection electrode CEa may be disposed in each of the first pixel circuit area PCAa and the fourth pixel circuit area PCAa' and may connect the first drain region DR1 of the first driving transistor T1a and the fifth source region SR5 of the first emission control transistor T5a through contact holes penetrating the circuit insulating layer.

The second source connection electrode SCE2a may be disposed in each of the first pixel circuit area PCAa and the fourth pixel circuit area PCAa' and may be connected to the second source region SR2 of the first data write transistor T2a through a contact hole penetrating the circuit insulating layer. A data line (e.g., the first data line DL1 or the second data line DL2 of FIG. 3), disposed to provide a data voltage, may be connected to the second source connection electrode SCE2a. The second drain connection electrode DCE2a may be disposed in each of the first pixel circuit area PCAa and the fourth pixel circuit area PCAa' and may be connected to the second drain region DR2 of the first data write transistor T2a through a contact hole penetrating the circuit insulating layer.

The third source connection electrode SCE3a may be disposed in each of the first pixel circuit area PCAa and the fourth pixel circuit area PCAa' and may be connected to the third source region SR3 of the first operation control transistor T3a through a contact hole penetrating the circuit insulating layer. A driving voltage line (e.g., the driving voltage line ELVDL of FIG. 3), disposed to provide a driving voltage, may be connected to the third source connection electrode SCE3a. The third drain connection electrode DCE3a may be disposed in each of the first pixel circuit area PCAa and the fourth pixel circuit area PCAa' and may be connected to the third drain region DR3 of the first operation control transistor T3a through a contact hole penetrating the circuit insulating layer.

The fourth source connection electrode SCE4amay be disposed in each of the first pixel circuit area PCAa and the fourth pixel circuit area PCAa' and may be connected to the fourth source region SR4 of the first initialization transistor T4a through a contact hole penetrating the circuit insulating layer. An initialization wiring (e.g., the first initialization line VIL1 or the second initialization line VIL2 of FIG. 3), disposed to provide an initialization voltage, may be connected to the fourth source connection electrode SCE4a. The fourth drain connection electrode DCE4a may be disposed in each of the first pixel circuit area PCAa and the fourth pixel circuit area PCAa' and may be connected to the fourth drain region DR4 of the first initialization transistor T4a through a contact hole penetrating the circuit insulating layer.

The fifth drain connection electrode DCE5a may be disposed in each of the first pixel circuit area PCAa and the fourth pixel circuit area PCAa' and may be connected to the fifth drain region DR5 of the first emission control transistor T5a through a contact hole penetrating the circuit insulating layer.

The first body connection electrode BCEa may be disposed in each of the first pixel circuit area PCAa and the fourth pixel circuit area PCAa' and may be connected to the first body electrode BEa through a contact hole penetrating the circuit insulating layer.

The first, second, third, and fourth source connection electrodes SCE1b, SCE2b, SCE3b, and SCE4b, the second, third, fourth, and fifth drain connection electrodes DCE2b, DCE3b, DCE4b, and DCE5b, the second gate connection electrode GCEb, the second connection electrode CEb, and the second body connection electrode BCEb may be disposed in each of the second pixel circuit area PCAb and the fifth pixel circuit area PCAb', and may be substantially the same as arrangement positions and connection methods as the first, second, third, and fourth source connection electrodes SCE1a, SCE2a, SCE3a,and SCE4a, the second, third, fourth, and fifth drain connection electrodes DCE2a, DCE3a, DCE4a, and DCE5a, the first gate connection electrode GCEa, the first connection electrode CEa, and the first body connection electrode BCEa. The first, second, third, and fourth source connection electrodes SCE1c, SCE2c, SCE3c, and SCE4c, the second, third, fourth, and fifth drain connection electrodes DCE2c, DCE3c, DCE4c, and DCE5c, the third gate connection electrode GCEc, the third connection electrode CEc, and the third body connection electrode BCEc may be disposed in each of the third pixel circuit area PCAc and the sixth pixel circuit area PCAc', and may be substantially the same as arrangement positions and connection methods as the first, second, third, and fourth source connection electrodes SCE1a, SCE2a, SCE3a, and SCE4a, the second, third, fourth, and fifth drain connection electrodes DCE2a, DCE3a, DCE4a, and DCE5a, the first gate connection electrode GCEa, the first connection electrode CEa, and the first body connection electrode BCEa.

In one or more embodiments, the second source connection electrode SCE2adisposed in the first pixel circuit area PCAa may have the same planar shape as the second source connection electrode SCE2c disposed in the third pixel circuit area PCAc, and the second source connection electrode SCE2bdisposed in the second pixel circuit area PCAb may have a planar shape that is symmetrical with respect to the planar shape of the second source connection electrode SCE2a disposed in the first pixel circuit area PCAa with respect to an axis extending in the first direction D1. Likewise, the second drain connection electrode DCE2a disposed in the first pixel circuit area PCAa may have the same planar shape as the second drain connection electrode DCE2c disposed in the third pixel circuit area PCAc, and the second drain connection electrode DCE2b disposed in the second pixel circuit area PCAb may have a planar shape that is symmetrical with respect to the planar shape of the second drain connection electrode DCE2a disposed in the first pixel circuit area PCAa with respect to an axis extending in the first direction D1.

In addition, the second source connection electrodes SCE2aand SCE2c and the second drain connection electrodes DCE2a and DCE2c disposed in the fourth and sixth pixel circuit areas PCAa' and PCAc', respectively, may have the same planar shapes as the second source connection electrode SCE2b and the second drain connection electrode DCE2b disposed in the second pixel circuit area PCAb, respectively, and the second source connection electrode SCE2b and the second drain connection electrode DCE2b disposed in the fifth pixel circuit area PCAb' may have the same planar shapes as the second source connection electrode SCE2a and the second drain connection electrode DCE2a disposed in the first pixel circuit area PCAa, respectively.

In one or more embodiments, the third source connection electrode SCE3a disposed in the first pixel circuit area PCAa may have the same planar shape as the third source connection electrode SCE3c disposed in the third pixel circuit area PCAc, and the third source connection electrode SCE3b disposed in the second pixel circuit area PCAb may have a planar shape that is symmetrical with respect to the planar shape of the third source connection electrode SCE3a disposed in the first pixel circuit area PCAa with respect to an axis extending in the first direction D1. Likewise, the third drain connection electrode DCE3a disposed in the first pixel circuit area PCAa may have the same planar shape as the third drain connection electrode DCE3cdisposed in the third pixel circuit area PCAc, and the third drain connection electrode DCE3b disposed in the second pixel circuit area PCAb may have a planar shape that is symmetrical with respect to the planar shape of the third drain connection electrode DCE3a disposed in the first pixel circuit area PCAa with respect to an axis extending in the first direction D1.

In addition, the third source connection electrodes SCE3a and SCE3cand the third drain connection electrodes DCE3aand DCE3c disposed in the fourth and sixth pixel circuit areas PCAa' and PCAc', respectively, may have the same planar shapes as the third source connection electrode SCE3b and the third drain connection electrode DCE3b disposed in the second pixel circuit area PCAb, respectively, and the third source connection electrode SCE3b and the third drain connection electrode DCE3b disposed in the fifth pixel circuit area PCAb' may have the same planar shapes as the third source connection electrode SCE3a and the third drain connection electrode DCE3a disposed in the first pixel circuit area PCAa, respectively.

The first write gate line GWL1 may extend in the first direction D1 and may be disposed in the first, second, third, fourth, fifth, and sixth pixel circuit areas PCAa, PCAb, PCAc, PCAa', PCAb', and PCAc'. The first write gate line GWL1 may be disposed in a first sub-row R-S1 of the first row R1. The first write gate line GWL1 may receive a first write gate signal (e.g., the first write gate signal GW1 of FIG. 3). In addition, the second write gate line GWL2 may extend in the first direction D1 and may be disposed in the first, second, third, fourth, fifth, and sixth pixel circuit areas PCAa, PCAb, PCAc, PCAa’, PCAb’, and PCAc’. The second write gate line GWL2 may be disposed in a second sub-row R-S2 adjacent to the first sub-row R-S1 in the direction opposite to the second direction D2 of the first row R1. The second write gate line GWL2 may receive a second write gate signal (e.g., the second write gate signal GW2 of FIG. 3).

In one or more embodiments, the first write gate line GWL1 may be connected to the second gate electrodes of the first, third, and fifth data write transistors T2a, T2c, and T2b' disposed in the first, third, and fifth pixel circuit areas PCAa, PCAc, and PCAb', respectively, through first, third, and fifth contact holes GCT1, GCT3, and GCT5 penetrating the circuit insulation layer. That is, the first write gate line GWL1 may be connected to the second gate electrode GE2a of the first data write transistor T2a through the first contact hole GCT1, may be connected to the second gate electrode GE2c of the third data write transistor T2c through the third contact hole GCT3, and may be connected to the second gate electrode of the fifth data write transistor T2b' through the fifth contact hole GCT5.

In one or more embodiments, the second write gate line GWL2 may be connected to the second gate electrodes of the second, fourth, and sixth data write transistors T2b, T2a', and T2c' disposed in the second, fourth, and sixth pixel circuit areas PCAb, PCAa', and PCAc', respectively, through second, fourth, and sixth contact holes GCT2, GCT4, and GCT6 penetrating the circuit insulation layer. That is, the second write gate line GWL2 may be connected to the second gate electrode GE2b of the second data write transistor T2b through the second contact hole GCT2, may be connected to the second gate electrode of the fourth data write transistor T2a' through the fourth contact hole GCT4, and may be connected to the second gate electrode of the sixth data write transistor T2c' through the sixth contact hole GCT6.

The second emission control line EML2 may extend in the first direction D1 and may be disposed in the first, second, third, fourth, fifth, and sixth pixel circuit areas PCAa, PCAb, PCAc, PCAa', PCAb', and PCAc'. The second emission control line EML2 may be disposed in a third sub-row R-S3 of a second row R2. The second emission control line EML2 may receive a second emission control signal (e.g., the second emission control signal EM2 of FIG. 3). In addition, the first emission control line EML1 may extend in the first direction D1 and may be disposed in the first, second, third, fourth, fifth, and sixth pixel circuit areas PCAa, PCAb, PCAc, PCAa', PCAb', and PCAc'. The first emission control line EML1 may be disposed in a fourth sub-row R-S4 adjacent to the third sub-row R-S3 in the direction opposite to the second direction D2 of the second row R2. The first emission control line EML1 may receive a first emission control signal (e.g., the first emission control signal EM1 of FIG. 3).

In one or more embodiments, the first emission control line EML1 may be connected to the third gate electrodes of the first, third, and fifth operation control transistors T3a, T3c, and T3b', respectively, through seventh, ninth, and eleventh contact holes ECT1, ECT3, and ECT5 penetrating the circuit insulation layer. That is, the first emission control line EML1 may be connected to the third gate electrode GE3a of the first operation control transistor T3a through the seventh contact hole ECT1, may be connected to the third gate electrode GE3c of the third operation control transistor T3c through the ninth contact hole ECT3, and may be connected to the third gate electrode of the fifth operation control transistor T3b' through the eleventh contact hole ECT5.

In one or more embodiments, the second emission control line EML2 may be connected to the third gate electrodes of the second, fourth, and sixth operation control transistors T3b, T3a', and T3c', respectively, through eighth, tenth, and twelfth contact holes ECT2, ECT4, and ECT6 penetrating the circuit insulation layer. That is, the second emission control line EML2 may be connected to the third gate electrode GE3b of the second operation control transistor T3b through the eighth contact hole ECT2, may be connected to the third gate electrode of the fourth operation control transistor T3a' through the tenth contact hole ECT4, and may be connected to the third gate electrode of the sixth operation control transistor T3c' through the twelfth contact hole ECT6.

As a result, in the present disclosure, the first, third, and fifth contact holes GCT1, GCT3, and GCT5 and the seventh, ninth, and eleventh contact holes ECT1, ECT3, and ECT5 may be formed in the first, third, and fifth pixel circuit areas PCAa, PCAc, and PCAb' disposed in odd-numbered columns (i.e., the first, third, and fifth columns C1, C3, and C5), and the second, fourth, and sixth contact holes GCT2, GCT4, and GCT6 and the eighth, tenth, and twelfth contact holes ECT2, ECT4, and ECT6 may be formed in the second, fourth, and sixth pixel circuit areas PCAb, PCAa', and PCAc' disposed in even-numbered columns (i.e., the second, fourth, and sixth columns C2, C4, and C6). Accordingly, as illustrated in FIGS. 10 and 11, in a structure in which the number of the write gate lines GWL1 and GWL2 disposed in one pixel circuit area is two and emission control lines EML1 and EML2 disposed in one pixel circuit area is two, and the write gate lines GWL1 and GWL2 and the emission control lines EML1 and EML2 are alternately connected to pixel driving circuit parts of the even-numbered columns and pixel driving circuit parts of the odd-numbered columns, the load deviation of the write gate lines GWL1 and GWL2 may be reduced or minimized, and the load deviation of the emission control lines EML1 and EML2 may be reduced or minimized.

In one or more embodiments, the first write gate line GWL1 may include first-first protrusions GP11 and first-second protrusions GP12 protruding in the direction opposite to the second direction D2, and the second write gate line GWL2 may include second-first protrusions GP21 and second-second protrusions GP22 protruding in the second direction D2. The first-first protrusions GP11 and second-first protrusions GP21 may be disposed in the first, third, and fifth pixel circuit areas PCAa, PCAc, and PCAb', and the first-second protrusions GP12 and the second-second protrusions GP22 may be disposed in the second, fourth, and sixth pixel circuit areas PCAb, PCAa', and PCAc', respectively. Accordingly, the areas of the first and second write gate lines GWL1 and GWL2 may be relatively increased, and the resistance of the first and second write gate lines GWL1 and GWL2 may be reduced or minimized.

For example, a width of each of the first-first protrusions GP11 in the first direction D1 may be greater than a width of each of the first-second protrusions GP12 in the first direction D1. In addition, a width of each of the second-first protrusions GP21 in the first direction D1 may be smaller than a width of each of the second-second protrusions GP22 in the first direction D1. However, the present disclosure is not necessarily limited thereto.

In one or more embodiments, the first write gate line GWL1 may include a first shielding portion SP1 protruding between the second drain connection electrode (e.g., DCE2b or DCE2a) and the second source connection electrode (e.g., SCE2c or SCE2b) adjacent to each other in the direction opposite to the second direction D2 from the first-first protrusions GP11. The second write gate line GWL2 may include a second shielding portion SP2 protruding between the second drain connection electrode (e.g., DCE2a or DCE2c) and the second source connection electrode (e.g., SCE2b or SCE2a) adjacent to each other in the second direction D2 from the second-second protrusions GP22. For example, the first shielding portion SP1 and the second shielding portion SP2 may be alternately arranged along the first direction D1.

Accordingly, the first shielding portion SP1 may shield electrical interference occurring between the second drain connection electrode (e.g., DCE2b or DCE2a) and the second source connection electrode (e.g., SCE2cor SCE2b) respectively disposed in two adjacent pixel circuit areas. The second shielding portion SP2 may shield electrical interference occurring between the second drain connection electrode (e.g., DCE2aor DCE2c) and the second source connection electrode (e.g., SCE2b or SCE2a) respectively disposed in two adjacent pixel circuit areas.

In one or more embodiments, portions of the first write gate line GWL1 disposed in the odd-numbered columns may have a planar shape, which is symmetrical with respect to the planar shape of portions of the second write gate line GWL2 disposed in the even-numbered columns with respect to an axis extending in the first direction D1, respectively. Likewise, the portions of the first write gate line GWL1 disposed in the even-numbered columns may have a planar shape which is symmetrical with respect to the planar shape of portions of the second write gate line GWL2 disposed in the odd-numbered columns with respect to an axis extending in the first direction D1.

In one or more embodiments, the first emission control line EML1 may include third-first protrusions EP11 and third-second protrusions EP12 protruding in the second direction D2, and the second emission control line EML2 may include fourth-first protrusions EP21 and fourth-second protrusions EP22 protruding in the direction opposite to the second direction D2. The third-first protrusions EP11 and the fourth-first protrusions EP21 may be disposed in the first, third, and fifth pixel circuit areas PCAa, PCAc, and PCAb′, and the third-second protrusions EP12 and the fourth-second protrusions EP22 may be disposed in the second, fourth, and sixth pixel circuit areas PCAb, PCAa′, and PCAc′, respectively. Accordingly, the areas of the first and second emission control lines EML1 and EML2 may be relatively increased, the resistance of the first and second emission control lines EML1 and EML2 may be reduced or minimized.

For example, a width of each of the third-first protrusions EP11 in the first direction D1 may be greater than a width of each of the third-second protrusions EP12 in the first direction D1. In addition, a width of each of the fourth-first protrusions EP21 in the first direction D1 may be smaller than a width of each of the fourth-second protrusions EP22 in the first direction D1. However, the present disclosure is not necessarily limited thereto.

In one or more embodiments, portions of the first emission control line EML1 disposed in the odd-numbered columns may have a planar shape that is symmetrical with respect to the planar shape of portions of the second emission control line EML2 disposed in the even-numbered columns with respect to an axis extending in the first direction D1, respectively. Likewise, portions of the first emission control line EML1 disposed in the even-numbered columns may have a planar shape that is symmetrical with respect to the planar shape of portions of the second emission control line EML2 disposed in the odd-numbered columns with respect to an axis extending in the first direction D1, respectively.

The initialization gate line EBL may extend in the first direction D1 and may be disposed in the first, second, third, fourth, fifth, and sixth pixel circuit areas PCAa, PCAb, PCAc, PCAa′, PCAb′, and PCAc′. The initialization gate line EBL may receive an initialization voltage (e.g., the initialization voltage VINT of FIG. 3). The initialization gate line EBL may be connected to the gate electrodes GE4a, GE4b, and GE4c of the first, second, third, fourth, fifth, and sixth initialization transistors T4a, T4b, T4c, T4a′, T4b′, and T4c′ through contact holes.

The emission control line ECL may extend in the first direction D1 and may be disposed in the first to sixth pixel circuit areas PCAa, PCAb, PCAc, PCAa′, PCAb′, and PCAc′. Specifically, the emission control line ECL may be disposed between the fourth row R4 and the fifth row R5. An emission control signal (for example, the emission control signal EC of FIG. 3) may be applied to the emission control line ECL. The emission control line ECL may be connected to the gate electrodes GE5a, GE5b, and GE5c of the first to sixth emission control transistors T5a, T5b, T5c, T5a′, T5b′, and T5c′ through contact holes.

The components illustrated in FIGS. 10 and 11 may be repeatedly arranged along the first direction D1 and the second direction D2.

In addition, a plurality of conductive layers may be further disposed on the metal layer illustrated in FIGS. 10 and 11. For example, the conductive layers may include the data lines DL1 and DL2, the driving voltage lines ELVDL1 and ELVDL2, the initialization lines VIL1 and VIL2, the first electrode of the capacitor CAP, the second electrode of the capacitor CAP, and the like as illustrated in FIG. 3.

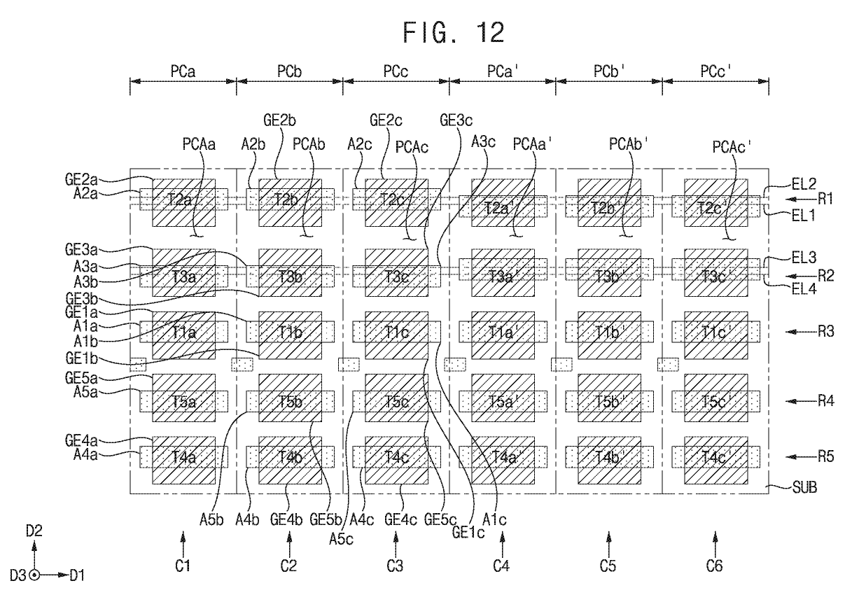

FIG. 12 is a layout view illustrating another example of first, second, third, fourth, fifth, and sixth pixel driving circuit parts included in the transistor substrate of FIG. 6.

However, in FIG. 12, the description of the first, second, third, fourth, fifth, and sixth pixel driving circuit parts PCa, PCb, PCc, PCa', PCb', and PCc' may be substantially the same as or similar to the description of the first, second, third, fourth, fifth, and sixth pixel driving circuit parts PCa, PCb, PCc, PCa', PCb', and PCc' of FIGS. 7, 8 and 9, except for the layout structures of the first, second, third, fourth, fifth, and sixth data input transistors T2a, T2b, T2c, T2a', T2b', and T2c' and the first, second, third, fourth, fifth, and sixth operation control transistors T3a, T3b, T3c, T3a', T3b', and T3c'. Hereinafter, redundant descriptions will be omitted or simplified.

Referring to FIG. 12, in one or more embodiments, the centers (i.e., centers of the channel regions) of the first, second, and third data input transistors T2a, T2b, and T2c disposed in the first, second, and third pixel circuit areas PCAa, PCAb, and PCAc may coincide with a virtual second line EL2 extending in the first direction D1, and the centers (i.e., centers of the channel regions) of the fourth, fifth, and sixth data input transistors T2a', T2b', and T2c' disposed in the fourth, fifth, and sixth pixel circuit areas PCAa', PCAb', and PCAc' may coincide with a virtual first line EL1 extending in the first direction D1. In this case, the virtual first line EL1 and the virtual second line EL2 may not overlap with each other and may be parallel to each other. However, the present disclosure is not necessarily limited thereto. In another embodiment, the centers (i.e., centers of the channel regions) of the first, second, third, fourth, fifth, and sixth data input transistors T2a, T2b, T2c, T2a', T2b', and T2c' disposed in the first, second, third, fourth, fifth, and sixth pixel circuit areas PCAa, PCAb, PCAc, PCAa', PCAb', and PCAc' may coincide with a single virtual line extending in the first direction D1.

In one or more embodiments, the centers (i.e., centers of the channel regions) of the first, second, and third operation control transistors T3a, T3b, and T3c disposed in the first, second, and third pixel circuit areas PCAa, PCAb, and PCAc may coincide with a virtual fourth line EL4 extending in the first direction D1, and the centers (i.e., centers of the channel regions) of the fourth to sixth operation control transistors T3a', T3b', and T3c' disposed in the fourth, fifth, and sixth pixel circuit areas PCAa', PCAb', and PCAc' may coincide with a virtual third line EL3 extending in the first direction D1. In this case, the virtual third line EL3 and the virtual fourth line EL4 may not overlap with each other and may be parallel to each other. However, the present disclosure is not necessarily limited thereto. In another embodiment, the centers (i.e., centers of the channel regions) of the first, second, third, fourth, fifth, and sixth operation control transistors T3a, T3b, T3c, T3a', T3b', and T3c' disposed in the first, second, third, fourth, fifth, and sixth pixel circuit areas PCAa, PCAb, PCAc, PCAa', PCAb', and PCAc' may coincide with a single virtual line extending in the first direction D1.

The components illustrated in FIG. 12 may be repeatedly arranged along the first direction D1 and the second direction D2.

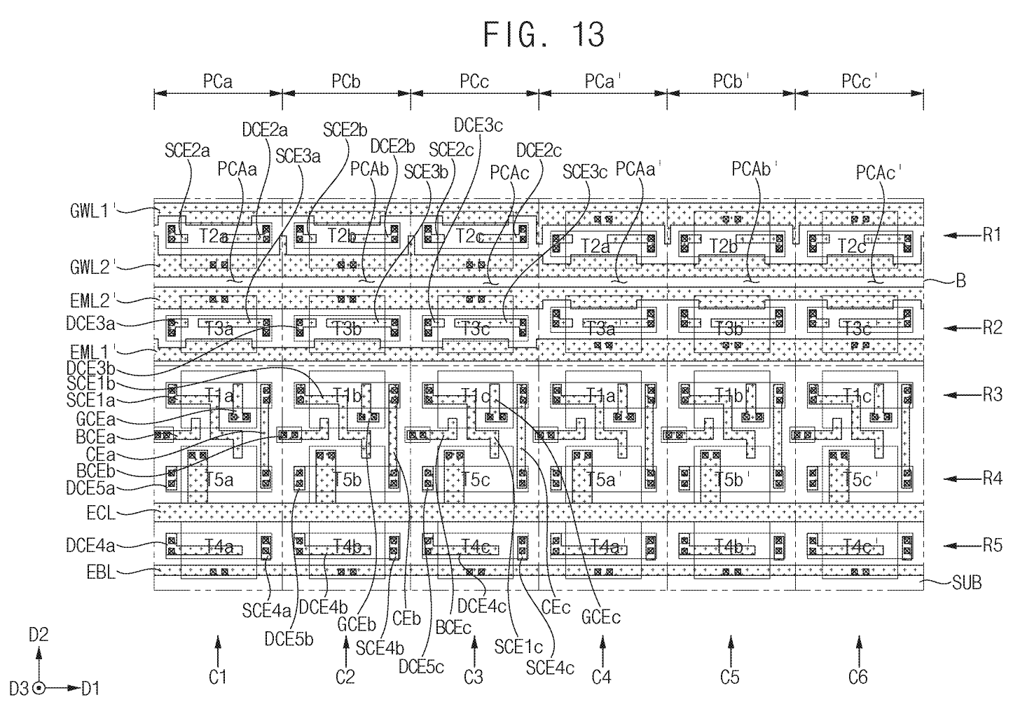

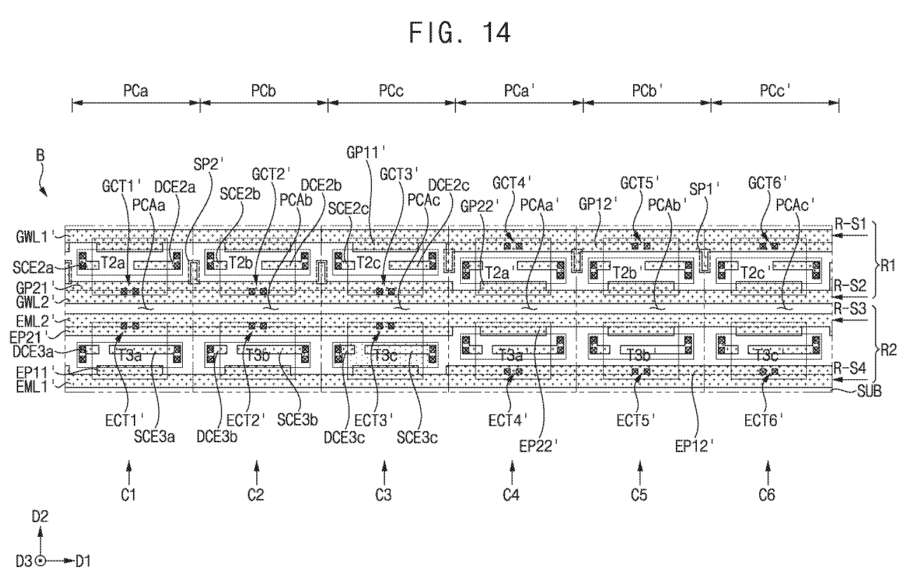

FIG. 13 is a layout view illustrating a metal layer disposed on the first, second, third, fourth, fifth, and sixth pixel driving circuit parts of FIG. 12. FIG. 14 is an enlarged layout view of area B of FIG. 13.

However, in FIGS. 13 and 14, the description of the metal layer may be substantially the same or similar to the description of the metal layer in FIGS. 10 and 11, except for the structures of a first writing gate line GWL1', a second writing gate line GWL2', a first emission control line EML1', a second emission control line EML2', the second source connection electrodes SCE2a, SCE2b, and SCE2c, the second drain connection electrodes DCE2a, DCE2b, and DCE2c, the third source connection electrodes SCE3a, SCE3b, and SCE3c, and the third drain connection electrodes DCE3a, DCE3b, and DCE3c. Hereinafter, redundant descriptions will be omitted or simplified.

Referring further to FIGS. 13 and 14, a circuit insulating layer may be disposed on the first, second, third, fourth, fifth, and sixth pixel driving circuit parts PCa, PCb, PCc, PCa', PCb', and PCc'. For example, the circuit insulating layer may include an inorganic insulating material or an organic insulating material.

A metal layer may be disposed on the circuit insulating layer. The metal layer may include the first source connection electrodes SCE1a, SCE1b, and SCE1c, the second source connection electrodes SCE2a, SCE2b, and SCE2c, the third source connection electrodes SCE3a, SCE3b, and SCE3c, the fourth source connection electrodes SCE4a, SCE4b, and SCE4c, the second drain connection electrodes DCE2a, DCE2b, and DCE2c, the third drain connection electrodes DCE3a, DCE3b, and DCE3c, the fourth drain connection electrodes DCE4a, DCE4b, and DCE4c, the fifth drain connection electrodes DCE5a, DCE5b, and DCE5c, the first, second, and third gate connection electrodes GCEa, GCEb, and GCEc, the first, second, and third connection electrodes CEa, CEb, and CEc, the first, second, and third body connection electrodes BCEa, BCEb, and BCEc, the first writing gate line GWL1', the second writing gate line GWL2', the first emission control line EML1', the second emission control line EML2', the emission control line ECL, and the initialization gate line EBL.

The components of the metal layer disposed on the first, second, third, fourth, fifth, and sixth driving transistors T1a, T1b, T1c, T1a', T1b', and T1c', the first, second, third, fourth, fifth, and sixth initialization transistors T4a, T4b, T4c, T4a', T4b', and T4c', and the first, second, third, fourth, fifth, and sixth emission control transistors T5a, T5b, T5c, T5a', T5b', and T5c' may be the same as those described with reference to FIGS. 10 and 11.

In one or more embodiments, the first writing gate line GWL1' may extend in the first direction D1 and may be disposed in the first, second, third, fourth, fifth, and sixth pixel circuit areas PCAa, PCAb, PCAc, PCAa', PCAb', and PCAc'. The first writing gate line GWL1' may be disposed in the first sub-row R-S1 of the first row R1. The first writing gate line GWL1' may receive a first writing gate signal (e.g., the first writing gate signal GW1 of FIG. 3). In addition, the second writing gate line GWL2' may extend in the first direction D1 and may be disposed in the first, second, third, fourth, fifth, and sixth pixel circuit areas PCAa, PCAb, PCAc, PCAa', PCAb', and PCAc'. The second writing gate line GWL2' may be disposed in the second sub-row R-S2 of the first row R1. The second writing gate line GWL2' may receive a second writing gate signal (e.g., the second writing gate signal GW2 of FIG. 3)

In one or more embodiments, the first writing gate line GWL1' may be connected to the second gate electrodes of the fourth, fifth, and sixth data writing transistors T2a', T2b', and T2c' disposed in the fourth, fifth, and sixth pixel circuit areas PCAa', PCAb', and PCAc' through fourth, fifth, and sixth contact holes GCT4', GCT5', and GCT6' penetrating the circuit insulating layer. That is, the first writing gate line GWL1' may be connected to the second gate electrode of the second data writing transistor T2a' through the fourth contact hole GCT4', be connected to the second gate electrode of the second data writing transistor T2b' through the fifth contact hole GCT5', and be connected to the second gate electrode of the second data writing transistor T2c' through the sixth contact hole GCT6'.

In one or more embodiments, the second writing gate line GWL2' may be connected to the second gate electrodes GE2a, GE2b, and GE2c of the first, second, and third data writing transistors T2a, T2b, and T2c disposed in the first, second, and third pixel circuit areas PCAa, PCAb, and PCAc through first, second, and third contact holes GCT1', GCT2', and GCT3' penetrating the circuit insulating layer. That is, the second writing gate line GWL2' may be connected to the second gate electrode GE2a of the first data writing transistor T2a through the first contact hole GCT1', be connected to the second gate electrode GE2b of the second data writing transistor T2b through the second contact hole GCT2', and be connected to the second gate electrode GE2c of the third data writing transistor T2c through the third contact hole GCT3'.

In one or more embodiments, the second emission control line EML2' may extend in the first direction D1 and may be disposed in the first, second, third, fourth, fifth, and sixth pixel circuit areas PCAa, PCAb, PCAc, PCAa', PCAb', and PCAc'. The second emission control line EML2’ may be disposed in the third sub-row R-S3 of the second row R2. The second emission control line EML2' may receive a second emission control signal (e.g., the second emission control signal EM2 of FIG. 3). In addition, the first emission control line EML1' may extend in the first direction D1 and may be disposed in the first, second, third, fourth, fifth, and sixth pixel circuit areas PCAa, PCAb, PCAc, PCAa', PCAb', and PCAc'. The first emission control line EML1' may be disposed in the fourth sub-row R-S4 of the second row R2. The first emission control line EML1' may receive a first emission control signal (e.g., the first emission control signal EM1 of FIG. 3).

In one or more embodiments, the first emission control line EML1' may be connected to the third gate electrodes of the fourth, fifth, and sixth operation control transistors T3a', T3b', and T3c' disposed in the fourth, fifth, and sixth pixel circuit areas PCAa', PCAb', and PCAc' through tenth, eleventh, and twelfth contact holes ECT4', ECT5', and ECT6' penetrating the circuit insulating layer. That is, the first emission control line EML1' may be connected to the third gate electrode of the fourth operation control transistor T3a' through the tenth contact hole ECT4', be connected to the third gate electrode of the fifth operation control transistor T3b through the eleventh contact hole ECT5', and be connected to the third gate electrode of the sixth operation control transistor T3c' through the twelfth contact hole ECT6'.

In one or more embodiments, the second emission control line EML2' may be connected to the third gate electrodes GE3a, GE3b, and GE3c of the first, second, and third operation control transistors T3a, T3b, and T3c disposed in the first, second, and third pixel circuit areas PCAa, PCAb, and PCAc through seventh, eighth, and ninth contact holes ECT1', ECT2', and ECT3' penetrating the circuit insulating layer. That is, the second emission control line EML2' may be connected to the third gate electrode GE3a of the first operation control transistor T3a through the seventh contact hole ECT1', be connected to the third gate electrode GE3b of the second operation control transistor T3b through the eighth contact hole ECT2', and be connected to the third gate electrode GE3c of the third operation control transistor T3c through the ninth contact hole ECT3'.

As a result, in the embodiments of the present disclosure, the fourth, fifth, and sixth contact holes GCT4', GCT5', and GCT6' and the tenth, eleventh, and twelfth contact holes ECT4', ECT5', and ECT6' may be formed in the fourth, fifth, and sixth pixel circuit areas PCAa', PCAb', and PCAc' disposed in the fourth, fifth, and sixth columns C4, C5, and C6, and the first, second, and third contact holes GCT1', GCT2', and GCT3' and the seventh, eighth, and ninth contact holes ECT1', ECT2', and ECT3' may be formed in the first, second, and third pixel circuit areas PCAa, PCAb, and PCAc disposed in the first, second, and third columns C1, C2, and C3. Such an arrangement of contact holes may be repeated in every six pixel circuit areas along the first direction D1. Accordingly, as illustrated in FIGS. 13 and 14, in the structure in which the number of the write gate lines GWL1' and GWL2' disposed in one pixel circuit area is two, the number of the emission control lines EML1' and EML2' disposed in one pixel circuit area is two, and each of the write gate lines GWL1' and GWL2' and the emission control lines EML1' and EML2' are alternately connected to every three adjacent pixel driving circuit parts, the load variation of the write gate lines GWL1' and GWL2' may be minimized and the load variation of the emission control lines EML1' and EML2' may be minimized.

In one or more embodiments, the first write gate line GWL1' may include first-first protrusions GP11' and first-second GP12' protruding in the direction opposite to the second direction D2, and the second write gate line GWL2' may include second-first protrusions GP21' and second-second protrusions GP22' protruding in the second direction D2. The first-first protrusions GP11' may be disposed in the first, second, and third pixel circuit areas PCAa, PCAb, and PCAc, and the first-second protrusions GP12' may extend across the fourth, fifth, and sixth pixel circuit areas PCAa', PCAb', and PCAc', respectively. In addition, the second-first protrusions GP21' may extend across the first, second, and third pixel circuit areas PCAa, PCAb, and PCAc, and the second-second protrusions GP22' may be disposed in the fourth to sixth pixel circuit areas PCAa', PCAb', and PCAc', respectively. Accordingly, the areas of the first and second write gate lines GWL1' and GWL2' may be relatively increased, and the resistance of the first and second write gate lines GWL1' and GWL2' may be minimized.

In one or more embodiments, the first write gate line GWL1' may include a first shielding portion SP1' protruding between adjacent a second drain connection electrode (e.g., DCE3c, DCE3a, or DCE3b) and a second source connection electrode (e.g., SCE3a, SCE3b, or SCE3c) from the first-second protrusions GP12' in the direction opposite to the second direction D2, and the second write gate line GWL2' may include a second shielding portion SP2' protruding between adjacent a second drain connection electrode (e.g., DCE2a or DCE2b) and a second source connection electrode (e.g., SCE2b or SCE2c) from the second-first protrusions GP21' in the second direction D2. For example, the first shielding portion SP1' may be respectively arranged between the third and fourth pixel circuit areas PCAc and PCAa', between the fourth and fifth pixel circuit areas PCAa' and PCAb', and between the fifth and sixth pixel circuit areas PCAb' and PCAc', and the second shielding portion SP2' may be respectively arranged between the first and second pixel circuit areas PCAa and PCAb, and between the second and third pixel circuit areas PCAb and PCAc.

Accordingly, the first shielding portion SP1’ may shield electrical interference occurring between the second drain connection electrode (e.g., DCE3c, DCE3a, or DCE3b) and the second source connection electrode (e.g., SCE3a, SCE3b, or SCE3c) disposed in two adjacent pixel circuit areas, respectively. The second shielding portion SP2' may shield electrical interference occurring between the second drain connection electrode (e.g., DCE2aor DCE2b) and the second source connection electrode (e.g., SCE2b or SCE2c) disposed in two adjacent pixel circuit areas, respectively.

In one or more embodiments, the portion of the first write gate line GWL1' disposed in the first, second, and third pixel circuit areas PCAa, PCAb, and PCAc may have a planar shape which is symmetrical with respect to the planar shape of the portion of the second write gate line GWL2' disposed in the fourth, fifth, and sixth pixel circuit areas PCAa', PCAb', and PCAc' with respect to an axis extending in the first direction D1. Likewise, the portion of the first write gate line GWL1' disposed in the fourth, fifth, and sixth pixel circuit areas PCAa', PCAb', and PCAc' may have a planar shape which is symmetrical with respect to the planar shape of the portion of the second write gate line GWL2' disposed in the first, second, and third pixel circuit areas PCAa, PCAb, and PCAc with respect to an axis extending in the first direction D1.

In one or more embodiments, the first emission control line EML1' may include third-first protrusions EP11' and third-second protrusions EP12' protruding in the second direction D2, and the second emission control line EML2' may include fourth-first protrusions EP21 and fourth-second protrusions EP22’ protruding in the direction opposite to the second direction D2. The third-first protrusions EP11' may be respectively disposed in the first, second, and third pixel circuit areas PCAa, PCAb, and PCAc, and the third-second protrusions EP12' may extend across the fourth, fifth, and sixth pixel circuit areas PCAa', PCAb', and PCAc'. In addition, the fourth-first protrusions EP21' may extend across the first, second, and third pixel circuit areas PCAa, PCAb, and PCAc, and the fourth-second protrusions EP22’ may be respectively disposed in the fourth, fifth, and sixth pixel circuit areas PCAa', PCAb', and PCAc'. Accordingly, the areas of the first and second emission control lines EML1' and EML2' may be relatively increased, and the resistance of the first and second emission control lines EML1' and EML2' may be minimized.

In one or more embodiments, the portion of the first emission control line EML1' disposed in the first, second, and third pixel circuit areas PCAa, PCAb, and PCAc may have a planar shape which is symmetrical with respect to the planar shape of the portion of the second emission control line EML2' disposed in the fourth, fifth, and sixth pixel circuit areas PCAa', PCAb', and PCAc' with respect to an axis extending in the first direction D1. Likewise, the portion of the first emission control line EML1' disposed in the fourth, fifth, and sixth pixel circuit areas PCAa', PCAb', and PCAc' may have a planar shape which is symmetrical with respect to the planar shape of the portion of the second emission control line EML2' disposed in the first, second, and third pixel circuit areas PCAa, PCAb, and PCAc with respect to an axis extending in the first direction D1.

The components illustrated in FIGS. 13 and 14 may be repeatedly arranged along the first direction D1 and the second direction D2.

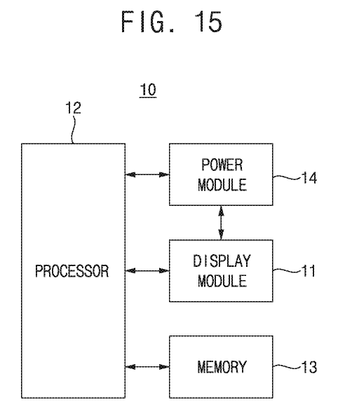

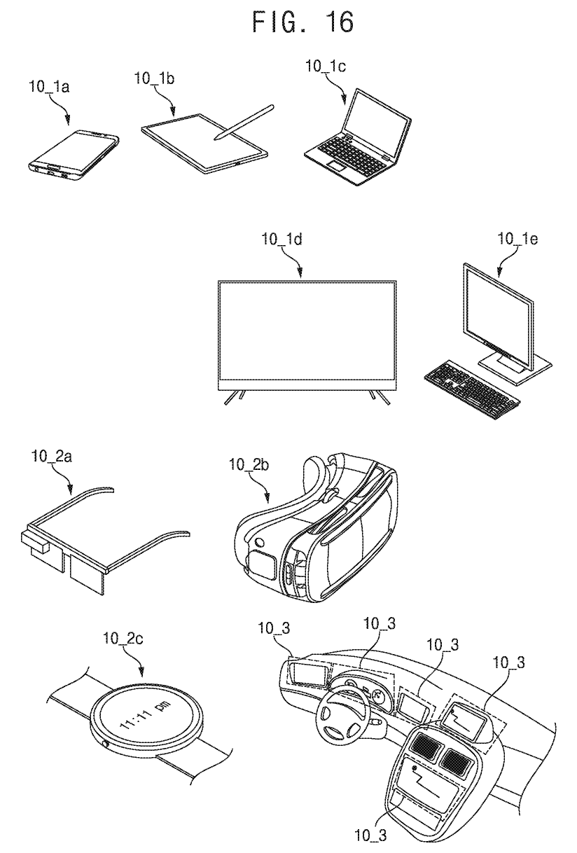

FIG. 15 is a block diagram illustrating an electronic device according to embodiments of the present disclosure.

Referring to FIG. 15, an electronic device 10 according to embodiments of the present disclosure may include a display module 11, a processor 12, a memory 13, and a power module 14.

A display device (e.g., the display device 100 of FIG. 1) according to embodiments of the present disclosure may be applied to various electronic devices. The electronic device 10 may include the display device described above, and may further include a module or device having additional functions in addition to the display device.

The processor 12 may include at least one of a central processing unit (CPU), an application processor (AP), a graphic processing unit (GPU), a communication processor (CP), and an image signal processor (ISP).

The memory 13 may store data information necessary for the operation of the processor 12 or the display module 11. In case that the processor 12 executes the application stored in the memory 13, an input image data (e.g., IDAT of FIG. 2) and/or a control signal (e.g., CTRL of FIG. 2) may be transmitted to the display module 11, and the display module 11 may process the received signal and output image information through a display screen.

The power module 14 may include a power supply module such as a power adapter or a battery device, and a power conversion module which converts an external power supplied by the power supply module to generate power required for the operation of the electronic device 10.

At least one of each component of the electronic device 10 described above may be included in the display device according to the above-described embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

FIG. 16 is a schematic diagram illustrating an electronic device according to various embodiments.

Referring to FIGS. 15 and 16, various electronic devices 10 to which display devices according to the embodiments are applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) disposed on a dashboard, and a room mirror display, or the like.

As described above, while the present disclosure has been explained with reference to embodiments, it will be understood by those of ordinary skill in the art that various modifications and changes can be made thereto without departing from the spirit and scope of the present disclosure as defined in the following claims.

The present disclosure may be applied to various display device which can be equipped with a display device. For example, the present disclosure may be applied to high-resolution smartphones, mobile phones, smart pads, smart watches, tablet PCs, vehicle navigation systems, televisions, computer monitors, and notebook computers.

What is claimed is:

1. A display device comprising:
a substrate including a first pixel circuit area and a second pixel circuit area located in a first direction from the first pixel circuit area;
a first driving transistor and a second driving transistor respectively located in the first and second pixel circuit areas and configured to generate a driving current;
a first data write transistor in the first pixel circuit area and configured to operate in response to a first write gate signal;
a second data write transistor in the second pixel circuit area and configured to operate in response to a second write gate signal;
a first write gate line in the first and second pixel circuit areas, extending in the first direction, and connected to a gate electrode of the first data write transistor;
a second write gate line in the first and second pixel circuit areas, extending in the first direction, adjacent to the first write gate line in a second direction crossing the first direction, and connected to a gate electrode of the second data write transistor;
a first light-emitting element electrically connected to the first driving transistor; and
a second light-emitting element electrically connected to the second driving transistor.

2. The display device of claim 1, wherein the first data write transistor is configured to receive a first data voltage or a first reference voltage having a voltage level different from the first data voltage, and
wherein the second data write transistor is configured to receive a second data voltage or a second reference voltage having a voltage level different from the second data voltage.

3. The display device of claim 1, further comprising:
a first operation control transistor adjacent to the first data write transistor in the second direction in the first pixel circuit area and configured to receive a driving voltage in response to a first emission control signal;
a second operation control transistor adjacent to the second data write transistor in the second direction in the second pixel circuit area and configured to receive a driving voltage in response to a second emission control signal;
a second emission control line in the first and second pixel circuit areas, adjacent to the second write gate line in the second direction, and connected to a gate electrode of the second operation control transistor; and
a first emission control line in the first and second pixel circuit areas, adjacent to the second emission control line in the second direction, and connected to a gate electrode of the first operation control transistor.

4. The display device of claim 3, wherein a center of a channel region of the first data write transistor coincides with a virtual first line extending in the first direction, and a center of a channel region of the second data write transistor coincides with a virtual second line which is parallel to the virtual first line and does not overlap the virtual first line, and
wherein a center of a channel region of the first operation control transistor coincides with a virtual third line which is parallel to the virtual first line and a center of a channel region of the second operation control transistor coincides with a virtual fourth line which is parallel to the virtual first line and does not overlap the virtual second line.

5. The display device of claim 3, further comprising:
a first source connection electrode connected to a source region of the first data write transistor;
a first drain connection electrode connected to a drain region of the first data write transistor;
a second source connection electrode connected to a source region of the second data write transistor; and
a second drain connection electrode connected to a drain region of the second data write transistor,
wherein the first source connection electrode has a planar shape which is symmetrical with respect to a planar shape of the second source connection electrode with respect to an axis extending in the first direction, and the second drain connection electrode has a planar shape which is symmetrical with respect to a planar shape of the first drain connection electrode with respect to the axis.

6. The display device of claim 5, wherein the first and second source connection electrodes and the first and second drain connection electrodes are located in a same layer as the first and second write gate lines.

7. The display device of claim 3, further comprising:
a third source connection electrode connected to a source region of the first operation control transistor;
a third drain connection electrode connected to a drain region of the first operation control transistor;
a fourth source connection electrode connected to a source region of the second operation control transistor; and
a fourth drain connection electrode connected to a drain region of the second operation control transistor,
wherein the third source connection electrode has a planar shape which is symmetrical with respect to a planar shape of the fourth source connection electrode with respect to an axis extending in the first direction, and the third drain connection electrode has a planar shape which is symmetrical with respect to a planar shape of the fourth drain connection electrode with respect to the axis.

8. The display device of claim 7, wherein the third and fourth source connection electrodes and the third and fourth drain connection electrodes are located in a same layer as the first and second emission control lines.

9. The display device of claim 3, wherein the first write gate line comprises a first-first protrusion and a first-second protrusion protruding in the second direction,
wherein the second write gate line comprises a second-first protrusion and a second-second protrusion protruding in a direction opposite to the second direction, and
wherein the first-first protrusion and the second-first protrusion are in the first pixel circuit area, and the first-second protrusion and the second-second protrusion are in the second pixel circuit area.

10. The display device of claim 9, wherein a width of the first-first protrusion in the first direction is different from a width of the first-second protrusion in the first direction, and
wherein a width of the second-first protrusion in the first direction is different from a width of the second-second protrusion in the first direction.

11. The display device of claim 9, wherein the first write gate line comprises a first shield portion protruding between the first data write transistor and another data write transistor adjacent to the first data write transistor from the first-first protrusion along the second direction, and
wherein the second write gate line comprises a second shield portion protruding between the first and second data write transistors from the second-second protrusion along a direction opposite to the second direction.

12. The display device of claim 3, wherein the first emission control line comprises a third-first protrusion and a third-second protrusion protruding in a direction opposite to the second direction,
wherein the second emission control line comprises a fourth-first protrusion and a fourth-second protrusion protruding in the second direction, and
wherein the third-first protrusion and the fourth-first protrusion are in the first pixel circuit area, and the third-second protrusion and the fourth-second protrusion are in the second pixel circuit area.

13. The display device of claim 12, wherein a width of the third-first protrusion in the first direction is different from a width of the third-second protrusion in the first direction, and
wherein a width of the fourth-first protrusion in the first direction is different from a width of the fourth-second protrusion in the first direction.

14. The display device of claim 3, further comprising:
a first emission control transistor adjacent to the first driving transistor in the second direction in the first pixel circuit area and connected to the first driving transistor;
a second emission control transistor adjacent to the second driving transistor in the second direction in the second pixel circuit area and connected to the second driving transistor;
a first initialization transistor adjacent to the first emission control transistor in the second direction in the first pixel circuit area and connected to the first emission control transistor and the first light-emitting element; and
a second initialization transistor adjacent to the second emission control transistor in the second direction in the second pixel circuit area and connected to the second emission control transistor and the second light-emitting element.

15. A display device comprising:
a substrate including a first pixel circuit area, a second pixel circuit area, a third pixel circuit area, and a fourth pixel circuit area arranged sequentially along a first direction;
a first driving transistor, a second driving transistor, a third driving transistor, and a fourth driving transistor which are respectively disposed in the first, second, third, and fourth pixel circuit areas and configured to generate a driving current;
a first data write transistor which is located in the first pixel circuit area and configured to operate in response to a first write gate signal;
a second data write transistor which is located in the second pixel circuit area and configured to operate in response to a second write gate signal;
a third data write transistor which is located in the third pixel circuit area and configured to operate in response to a third write gate signal;
a fourth data write transistor which is located in the fourth pixel circuit area and configured to operate in response to a fourth write gate signal;
a first write gate line located in the first, second, third, and fourth pixel circuit areas, extending in the first direction, and connected to a gate electrode of the first data write transistor and a gate electrode of the third data write transistor;
a second write gate line located in the first, second, third, and fourth pixel circuit areas, extending in the first direction, adjacent to the first write gate line in a second direction intersecting the first direction, and connected to a gate electrode of the second data write transistor and a gate electrode of the fourth data write transistor; and
a first light-emitting element, a second light-emitting element, a third light-emitting element, and a fourth light-emitting element electrically connected to the first, second, third, and fourth driving transistors, respectively.

16. The display device of claim 15, further comprising:
a first operation control transistor which is adjacent to the first data write transistor in the second direction in the first pixel circuit area and configured to receive a driving voltage in response to a first emission control signal;
a second operation control transistor which is adjacent to the second data write transistor in the second direction in the second pixel circuit area and configured to receive the driving voltage in response to a second emission control signal;
a third operation control transistor which is adjacent to the third data write transistor in the second direction in the third pixel circuit area and configured to receive the driving voltage in response to the first emission control signal;
a fourth operation control transistor which is adjacent to the fourth data write transistor in the second direction in the fourth pixel circuit area and configured to receive the driving voltage in response to the second emission control signal;
a second emission control line located in the first, second, third, and fourth pixel circuit areas, extending in the first direction, adjacent to the second write gate line in the second direction, and connected to a gate electrode of the second operation control transistor and a gate electrode of the fourth operation control transistor; and
a first emission control line located in the first, second, third, and fourth pixel circuit areas, extending in the first direction, adjacent to the second emission control line in the second direction, and connected to a gate electrode of the first operation control transistor and a gate electrode of the third operation control transistor.

17. An electronic device comprising:
a display device; and
a processor which provides input image data and control signal to the display device to control the display device,
wherein the display device comprises:
a substrate including a first pixel circuit area and a second pixel circuit area located in a first direction from the first pixel circuit area;
a first driving transistor and a second driving transistor which are respectively disposed in the first and second pixel circuit areas and configured to generate a driving current;
a first data write transistor which is located in the first pixel circuit area and configured to operate in response to a first write gate signal;
a second data write transistor which is located in the second pixel circuit area and configured to operate in response to a second write gate signal;
a first write gate line located in the first and second pixel circuit areas, extending in the first direction, and connected to a gate electrode of the first data write transistor;
a second write gate line located in the first and second pixel circuit areas, extending in the first direction, adjacent to the first write gate line in a second direction intersecting the first direction, and connected to a gate electrode of the second data write transistor;
a first light-emitting element electrically connected to the first driving transistor; and
a second light-emitting element electrically connected to the second driving transistor.

18. The electronic device of claim 17, wherein the display device further comprises:
a first operation control transistor which is adjacent to the first data write transistor in the second direction in the first pixel circuit area and configured to receive a driving voltage in response to a first emission control signal;
a second operation control transistor which is adjacent to the second data write transistor in the second direction in the second pixel circuit area and configured to receive a driving voltage in response to a second emission control signal;
a second emission control line in the first and second pixel circuit areas, adjacent to the second write gate line in the second direction, and connected to a gate electrode of the second operation control transistor; and
a first emission control line in the first and second pixel circuit areas, adjacent to the second emission control line in the second direction, and connected to a gate electrode of the first operation control transistor.

19. The electronic device of claim 18, wherein the display device further comprises:
a first source connection electrode connected to a source region of the first data write transistor;
a first drain connection electrode connected to a drain region of the first data write transistor;
a second source connection electrode connected to a source region of the second data write transistor; and
a second drain connection electrode connected to a drain region of the second data write transistor,
wherein the first source connection electrode has a planar shape which is symmetrical with respect to a planar shape of the second source connection electrode with respect to an axis extending in the first direction, and the second drain connection electrode has a planar shape which is symmetrical with respect to a planar shape of the first drain connection electrode with respect to the axis.

20. The electronic device of claim 19, wherein the display device further comprises:
a third source connection electrode connected to a source region of the first operation control transistor;
a third drain connection electrode connected to a drain region of the first operation control transistor;
a fourth source connection electrode connected to a source region of the second operation control transistor; and
a fourth drain connection electrode connected to a drain region of the second operation control transistor,
wherein the third source connection electrode has a planar shape which is symmetrical with respect to a planar shape of the fourth source connection electrode with respect to an axis extending in the first direction, and the third drain connection electrode has a planar shape which is symmetrical with respect to a planar shape of the fourth drain connection electrode with respect to the axis.
